(19) United States
(12) Patent Application Publication
(10) Pub. No.: US 2024/0280764 A1
(43) Pub. Date: Aug. 22, 2024

(54) PHOTONIC SEMICONDUCTOR DEVICE AND METHOD OF MANUFACTURE

(71) Applicant: Taiwan Semiconductor Manufacturing Co., Ltd., Hsinchu (TW)

(72) Inventors: Tsung-Fu Tsai, Changhua (TW); Chen-Hua Yu, Hsinchu (TW); Szu-Wei Lu, Hsinchu (TW); Chao-Jen Wang, Hsinchu (TW)

(21) Appl. No.: 18/364,332

(22) Filed: Aug. 2, 2023

Related U.S. Application Data
(63) Continuation-in-part of application No. 18/347,169, filed on Jul. 5, 2023, now abandoned.
(60) Provisional application No. 63/485,697, filed on Feb. 17, 2023.

(51) Int. Cl. G02B 6/42

(52) U.S. Cl. CPC G02B 6/4206; G02B 6/4239; G02B 6/4245

(57) ABSTRACT

A method includes connecting a photonic package to a substrate, wherein the photonic package includes a waveguide and an edge coupler that is optically coupled to the waveguide; connecting a semiconductor device to the substrate adjacent the photonic package; depositing a first protection material on a first sidewall of the photonic package that is adjacent the edge coupler; encapsulating the photonic package and the semiconductor device with an encapsulant; performing a first sawing process through the encapsulant and the substrate, wherein the first sawing process exposes the first protection material; and removing the first protection material to expose the first sidewall of the photonic package.

### PRIORITY CLAIM AND CROSS-REFERENCE

This application is a continuation in part of U.S. patent application Ser. No. 18/347,169, filed on Jul. 5, 2023 entitled “Photonic Semiconductor Device and Method of Manufacture,” which claims the benefits of U.S. Provisional Application No. 63/485,697, filed on Feb. 17, 2023, which application is hereby incorporated herein by reference in its entirety.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 11 illustrate cross-sectional views of intermediate steps of forming a photonic package, in accordance with some embodiments.

FIGS. 12, 13, 14, and 15 illustrate cross-sectional views of intermediate steps of singulating photonic packages, in accordance with some embodiments.

FIGS. 16, 17, 18, 19, and 20 illustrate cross-sectional views of intermediate steps of forming a photonic package, in accordance with some embodiments.

FIGS. 21A, 21B, 22, 23, 24, 25A, 25B, 25C, 26A, 26B, and 26C illustrate various views of intermediate steps of forming a photonic system, in accordance with some embodiments.

FIGS. 27A and 27B illustrate cross-sectional views of fiber array units, in accordance with some embodiments.

FIGS. 28A, 28B, and 28C illustrate various views of a photonic system, in accordance with some embodiments.

FIG. 29 illustrates a cross-sectional view of a photonic system, in accordance with some embodiments.

FIGS. 30, 31, 32, and 33 illustrate various views of intermediate steps of forming a photonic system, in accordance with some embodiments.

FIG. 34 illustrates a cross-sectional view of a photonic system, in accordance with some embodiments.

FIG. 35 illustrates a cross-sectional view of a photonic system, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, various aspects of a photonic system and the formation thereof are described. A photonic system comprising photonic packages including both optical devices and electrical devices, and the method of forming the same are provided, in accordance with some embodiments. In particular, a photonic package in a photonic system may be configured to communicate optical signals and/or optical power to optical fibers using edge couplers. For example, each photonic package may comprise waveguides with edge couplers, with the edge couplers of the adjacent photonic packages being optically coupled with adjacent optical fibers. Techniques described herein allow for the singulation of photonic packages with reduced risk of damage to the sidewalls adjacent the edge couplers. Additionally, the sidewalls adjacent the edge couplers may have a smoother surface using the techniques described herein, which can improve optical coupling. The use of sacrificial protective layers throughout manufacturing also provides protection for the sidewalls adjacent the edge couplers. Additionally, a fiber holder (e.g., a fiber array unit or the like) is described that allows for the height of the photonic system to be reduced. Some variations of some embodiments are discussed. Throughout the various views and illustrative embodiments, like reference numbers are used to designate like elements.

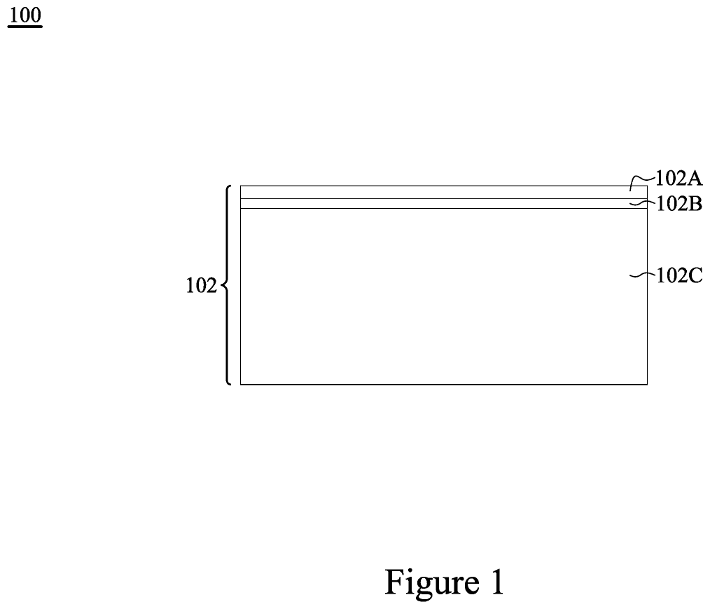

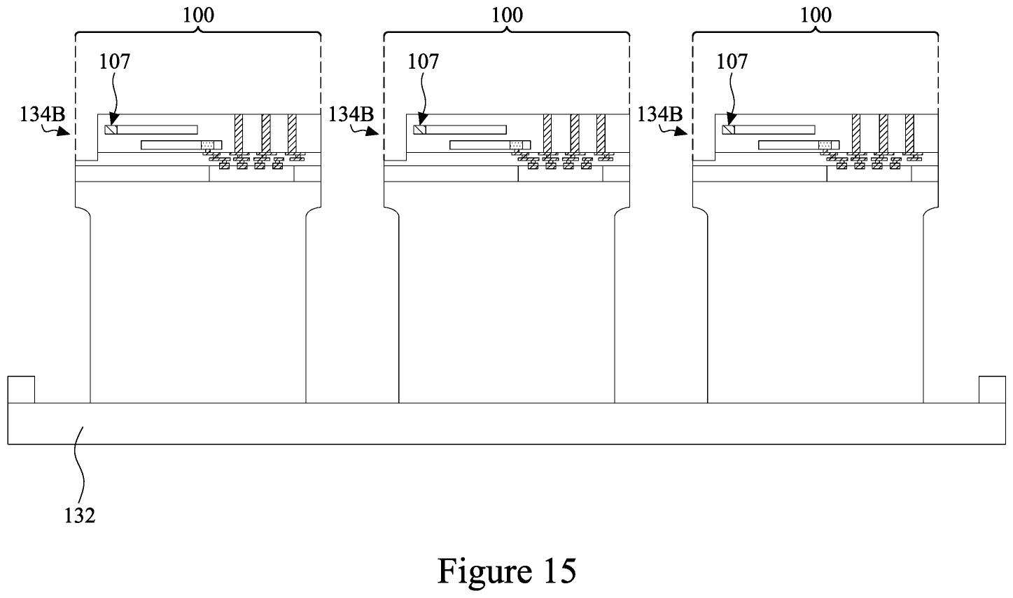

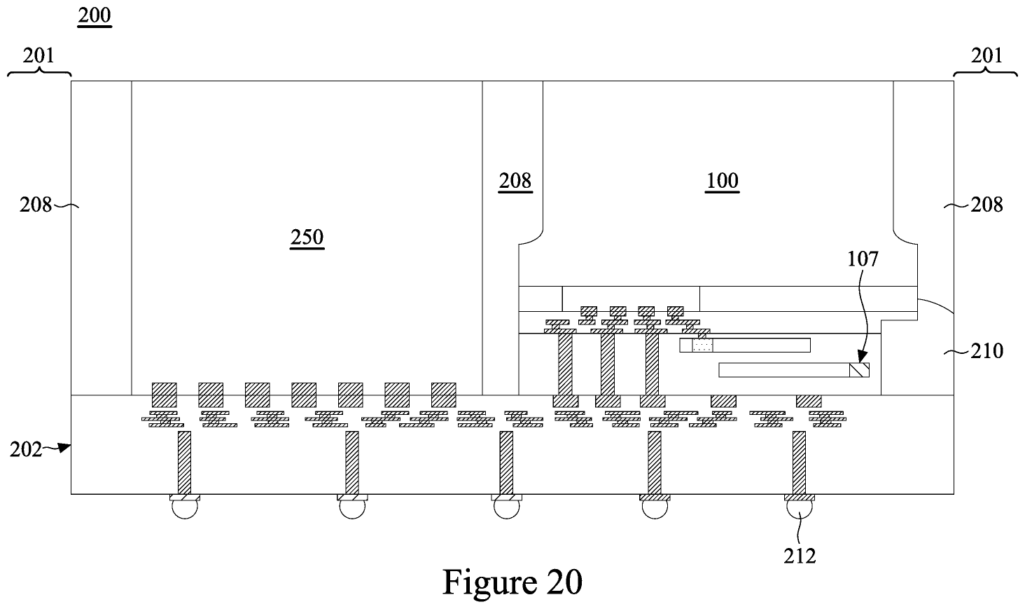

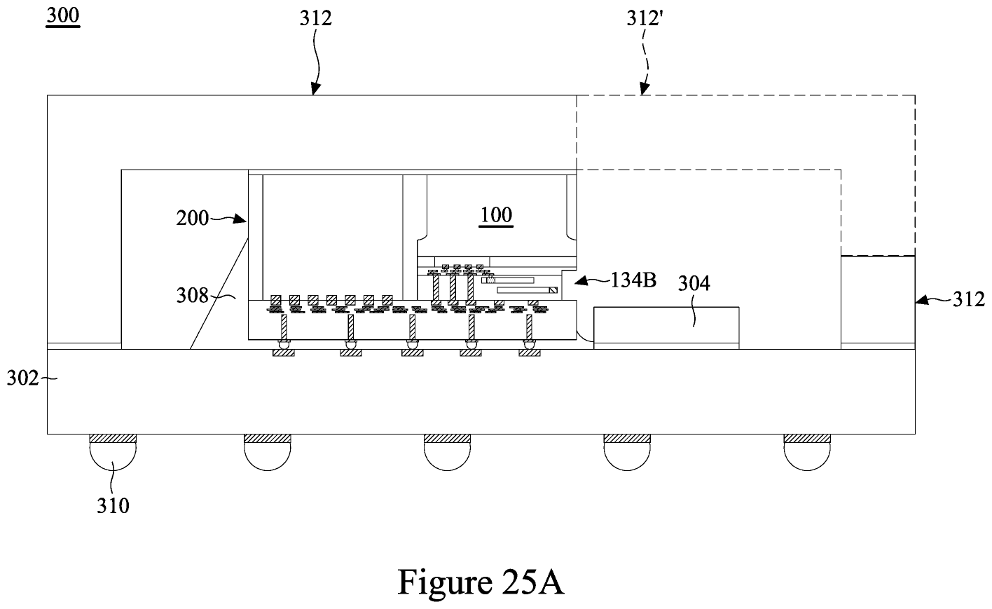

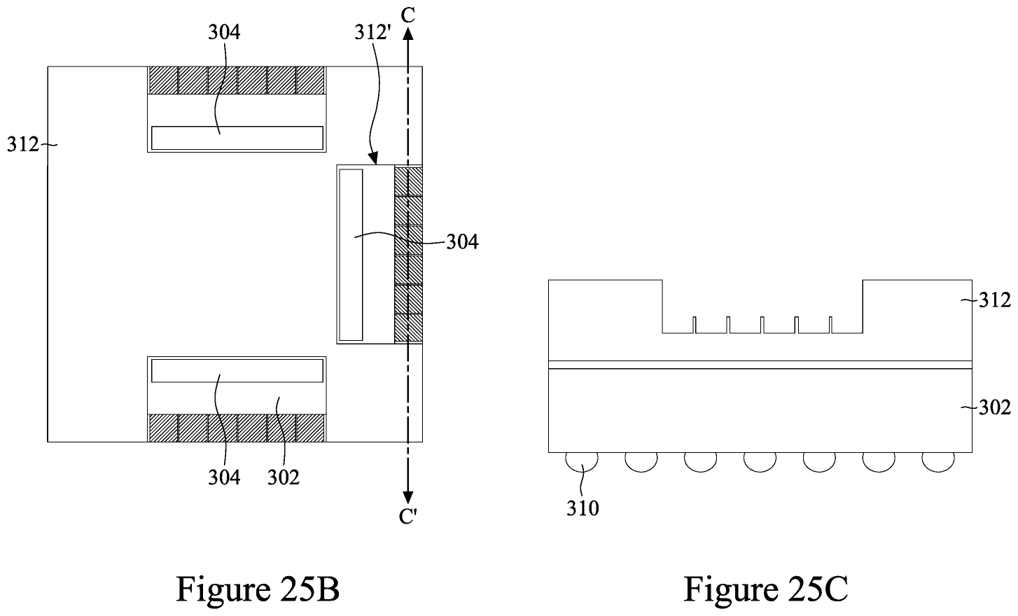

FIGS. 1 through 15 show cross-sectional views of intermediate steps of forming a photonic package 100 (see FIG. 15), in accordance with some embodiments. In some embodiments, the photonic package 100 may act as an input/output (I/O) interface between optical signals and electrical signals. For example, one or more photonic packages may be used in a photonic structure such as the photonic structure 200 (see FIG. 20), a photonic system such as the photonic system 300 (see FIG. 25), or the like. In some embodiments, multiple photonic packages 100 are formed on the same substrate (e.g., substrate 102 of FIG. 1) and then subsequently singulated into individual photonic packages 100.

Turning first to FIG. 1, a buried oxide (“BOX”) substrate 102 is provided, in accordance with some embodiments. The BOX substrate 102 includes an oxide layer 102B formed over a substrate 102C, and a silicon layer 102A formed over the oxide layer 102B. The substrate 102C may be, for example, a material such as a glass, ceramic, dielectric, a semiconductor, the like, or a combination thereof. In some embodiments, the substrate 102C may be a semiconductor substrate, such as a bulk semiconductor or the like, which may be doped (e.g., with a p-type dopant and/or an n-type dopant) or undoped. The substrate 102C may be a wafer, such as a silicon wafer or the like. Other substrates, such as a multi-layered or gradient substrate may also be used. In some embodiments, the semiconductor material of the substrate 102C may include silicon; germanium; a compound semiconductor including silicon carbide, gallium arsenic, gallium phosphide, indium phosphide, indium arsenide, and/or indium antimonide; an alloy semiconductor including silicon germanium, GaAsP, AlInAs, AlGaAs, GaInAs, GaInP, and/or GaInAsP; or combinations thereof. The oxide layer 102B may be, for example, a silicon oxide or the like. In some embodiments, the oxide layer 102B may have a thickness between about 0.5 μm and about 4 μm. The silicon layer 102A may have a thickness between about 0.1 μm and about 1.5 μm, in some embodiments. Other thicknesses or materials are possible. The BOX substrate 102 may be referred to as having a front side or front surface (e.g., the side facing upwards in FIG. 1), and a back side or back surface (e.g., the side facing downwards in FIG. 1).

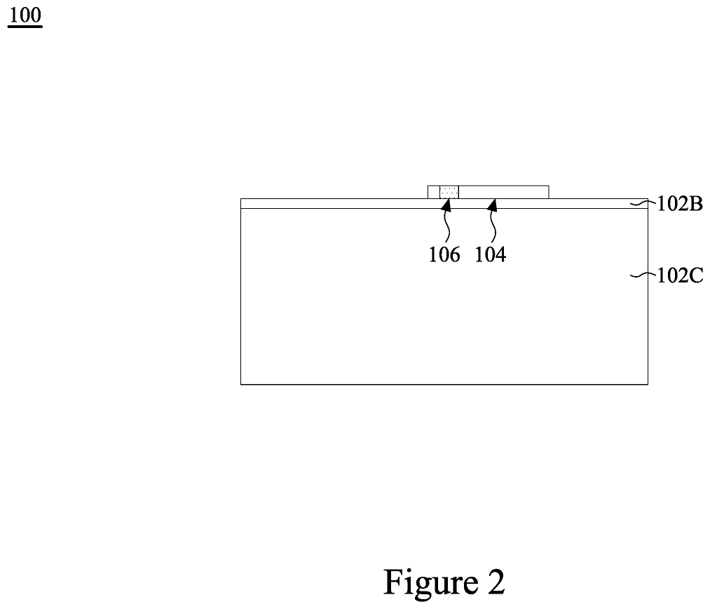

In FIG. 2, the silicon layer 102A is patterned to form silicon regions for waveguides 104 and photonic components 106, in accordance with some embodiments. The silicon layer 102A may be patterned using suitable photolithography and etching techniques. For example, a hardmask layer (e.g., a nitride layer or other dielectric material, not shown in FIG. 2) may be formed over the silicon layer 102A and patterned, in some embodiments. The pattern of the hardmask layer may then be transferred to the silicon layer 102A using one or more etching techniques, such as dry etching and/or wet etching techniques. For example, the silicon layer 102A may be etched to form recesses defining the waveguides 104, with sidewalls of the remaining unrecessed portions defining sidewalls of the waveguides 104. In some embodiments, more than one photolithography and etching sequence may be used in order to pattern the silicon layer 102A. One waveguide 104 or multiple waveguides 104 may be patterned from the silicon layer 102A. If multiple waveguides 104 are formed, the multiple waveguides 104 may be individual separate waveguides 104 or connected as a single continuous structure. In some embodiments, one or more of the waveguides 104 form a continuous loop. Other configurations or arrangements of waveguides 104 or photonic components 106 are possible.

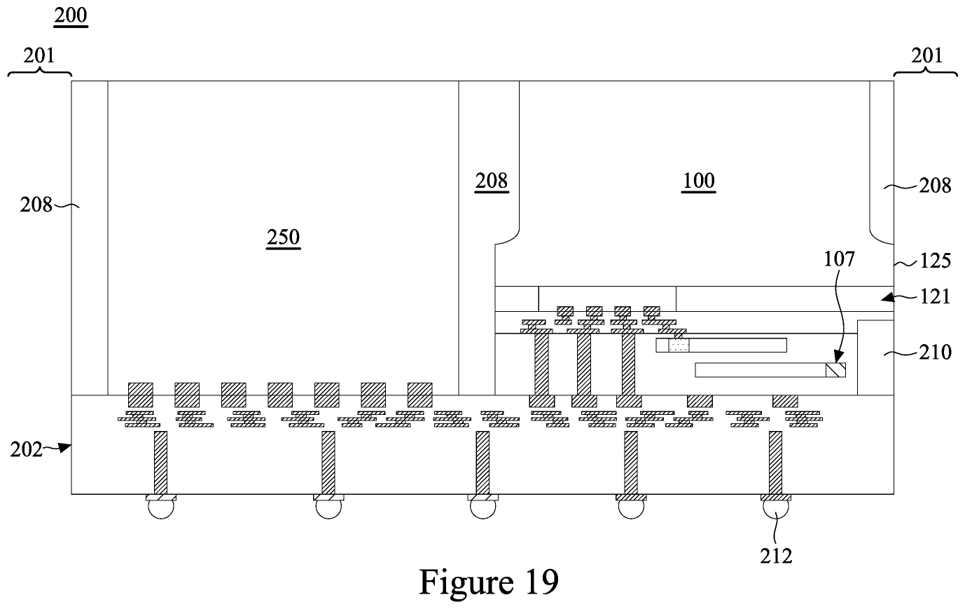

The photonic components 106 may be integrated with the waveguides 104, and may be formed with the silicon waveguides 104 in some embodiments. The photonic components 106 may be physically and/or optically coupled to the waveguides 104 to interact with optical signals within the waveguides 104. The photonic components 106 may include, for example, photodetectors and/or modulators. For example, a photodetector may be optically coupled to a waveguide 104 to detect optical signals within that waveguide 104 and generate electrical signals corresponding to the optical signals. A modulator may be optically coupled to a waveguide 104 to receive electrical signals and generate corresponding optical signals within that waveguide 104 by modulating optical power within that waveguide 104. In this manner, the photonic components 106 can facilitate the input/output (I/O) of optical signals to and from the waveguides 104. In some embodiments, the photonic components 106 may include other active or passive components, such as laser diodes, optical signal splitters, mode converters, oscillators, grating couplers, edge couplers, evanescent couplers, or other types of photonic structures or devices. Optical power may be provided to the waveguides 104, for example, by an optical fiber (not shown) coupled to an external light source or by a photonic component within the photonic package 100 such as a laser diode (not shown in the figures). In some embodiments, optical power and/or optical signals may be transmitted to the waveguides 104 from an adjacent photonic package (e.g. photonic package 100 of FIG. 19). For example, the adjacent photonic package may comprise a waveguide or a laser diode that is optically coupled to the waveguides 104 by an edge coupler or the like.

In some embodiments, the photodetectors may be formed by, for example, partially etching regions of the patterned silicon layer 102A (which may include the waveguides 104) and growing an epitaxial material on the remaining silicon of the etched regions. The etching may utilize acceptable photolithography and etching techniques. The epitaxial material may comprise, for example, a semiconductor material such as germanium, silicon-germanium, or the like, which may be doped or undoped. In some embodiments, an implantation process may be performed to introduce dopants within the silicon of the etched regions as part of the formation of the photodetectors. The silicon of the etched regions may be doped with p-type dopants, n-type dopants, or a combination thereof. In some embodiments, the modulators may be formed by, for example, partially etching regions of the silicon layer 102A (which may include the waveguides 104) and then implanting appropriate dopants within the remaining silicon of the etched regions. The etching may utilize acceptable photolithography and etching techniques. In some embodiments, the etched regions used for the photodetectors and the etched regions used for the modulators may be formed using one or more of the same photolithography or etching steps. The silicon of the etched regions may be doped with p-type dopants, n-type dopants, or a combination thereof. In some embodiments, the etched regions used for the photodetectors and the etched regions used for the modulators may be implanted using one or more of the same implantation steps. Other photonic components 106, other materials, or other manufacturing steps are possible.

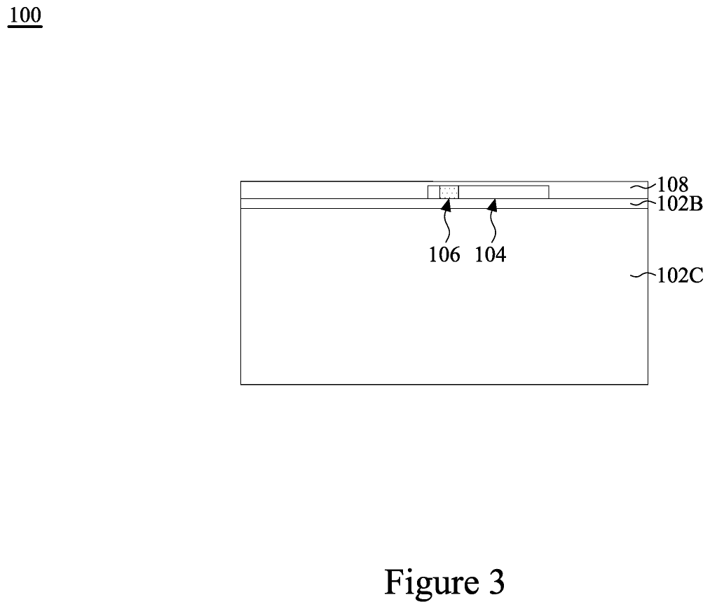

In FIG. 3, a dielectric layer 108 is formed on the front side of the BOX substrate 102, in accordance with some embodiments. The dielectric layer 108 is formed over the waveguides 104, the photonic components 106, and the oxide layer 102B. The dielectric layer 108 may be formed of one or more layers of silicon oxide, silicon nitride, a combination thereof, or the like, and may be formed by CVD, PVD, atomic layer deposition (ALD), a spin-on-dielectric process, the like, or a combination thereof. In some embodiments, the dielectric layer 108 may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other dielectric materials formed by any acceptable process may be used. In some embodiments, the dielectric layer 108 is then planarized using a planarization process such as a CMP process, a grinding process, or the like. The dielectric layer 108 may be formed having a thickness over the oxide layer 102B between about 50 nm and about 500 nm, or may be formed having a thickness over the waveguides 104 between about 10 nm and about 200 nm, in some embodiments. Other thicknesses are possible. In other embodiments, top surfaces of the waveguides 104 and/or the photonic components 106 are exposed by the planarization process.

Due to the difference in refractive indices of the materials of the waveguides 104 and dielectric layer 108, the waveguides 104 have high internal reflection such that light is substantially confined within the waveguides 104, depending on the wavelength of the light and the refractive indices of the respective materials. In an embodiment, the refractive index of the material of the waveguides 104 is higher than the refractive index of the material of the dielectric layer 108. For example, the waveguides 104 may comprise silicon, and the dielectric layer 108 may comprise silicon oxide and/or silicon nitride. Other materials are possible.

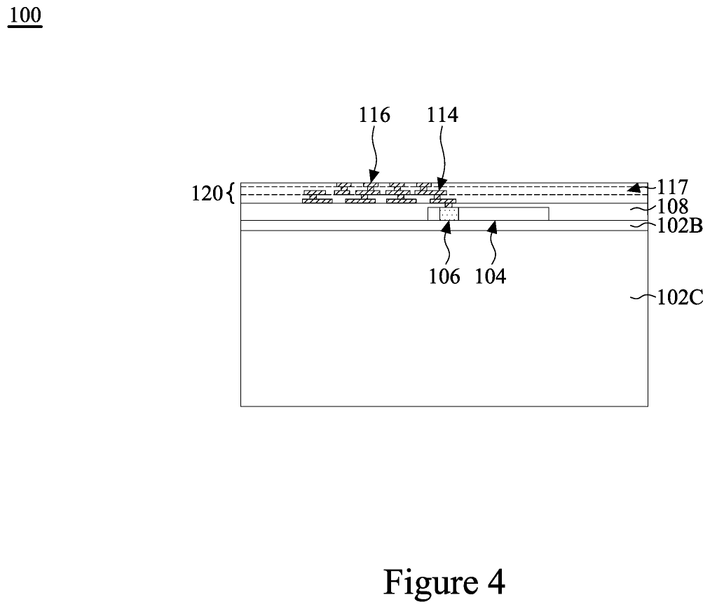

In FIG. 4, a redistribution structure 120 is formed over the dielectric layer 108, in accordance with some embodiments. The redistribution structure 120 includes conductive features 114 formed in one or more dielectric layers 117. The conductive features 114 provide interconnections and electrical routing. The dielectric layers 117 may be, for example, insulating or passivating layers, and may comprise one or more materials similar to those described above for the dielectric layer 108, such as a silicon oxide or a silicon nitride, though other materials are possible. The dielectric layers 117 and the dielectric layer 108 may be transparent or nearly transparent to light within the same range of wavelengths, in some embodiments. The dielectric layers 117 may be formed using a technique similar to those described above for the dielectric layer 108 or using a different technique.

The conductive features 114 may include conductive lines, conductive vias, and conductive pads 116. The conductive features 114 may be formed using a damascene process (e.g., single damascene, duel damascene), the like, or another process. The conductive features 114 may comprise a metal or a metal alloy including aluminum, copper, tungsten, or the like, though other materials are possible. As shown in FIG. 4, conductive pads 116 are formed in the topmost layer of the dielectric layers 117. A planarization process (e.g., a CMP process or the like) may be performed after forming the conductive pads 116 such that surfaces of the conductive pads 116 and the topmost dielectric layer 117 are substantially coplanar (e.g., level). In some cases, the topmost dielectric layer 117 may comprise a material suitable for dielectric-to-dielectric bonding, and may thus be considered a “bonding layer.” The redistribution structure 120 may include more or fewer dielectric layers 117, conductive features 114, or conductive pads 116 than shown in FIG. 4, and may have a different arrangement or configuration. The redistribution structure 120 may be formed having a thickness between about 4 μm and about 6 μm, in some embodiments. Other thicknesses are possible.

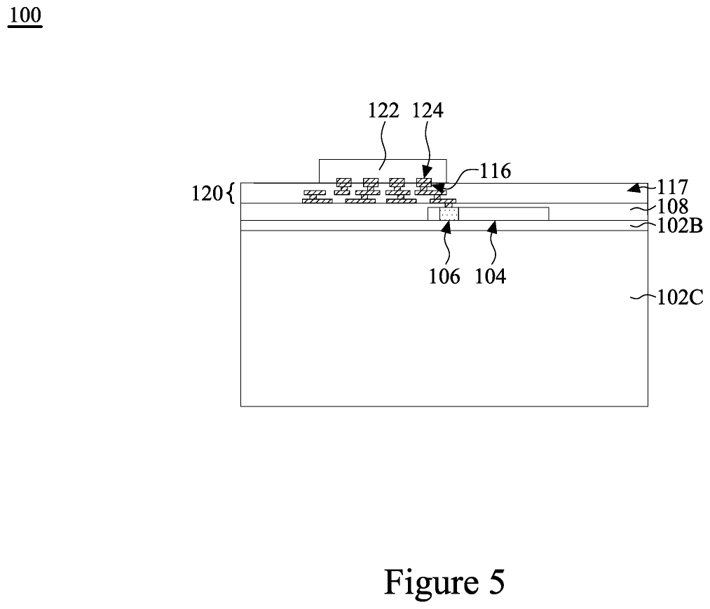

In some embodiments, the redistribution structure 120 may comprise one or more contacts that are electrically connected to one or more photonic components 106. The contacts may extend through portions of the dielectric layer 108, in some cases. The contacts to the photonic components 106 allow electrical power or electrical signals to be transmitted to the photonic components 106 and electrical signals to be transmitted from the photonic components 106. In this manner, the photonic components 106 may convert electrical signals (e.g., from an electronic die 122, see FIG. 5) into optical signals transmitted by the waveguides 104, and/or convert optical signals from the waveguides 104 into electrical signals (e.g., that may be received by an electronic die 122).

In FIG. 5, one or more electronic dies 122 are bonded to the redistribution structure 120, in accordance with some embodiments. The electronic dies 122 may be, for example, semiconductor devices, dies, or chips that communicate with the photonic components 106 using electrical signals. One electronic die 122 is shown in FIG. 5, but a photonic package 100 may include two or more electronic dies 122 in other embodiments. In some cases, multiple electronic dies 122 may be incorporated into a single photonic package 100 in order to reduce processing cost. The electronic die 122 may include die connectors 124, which may be, for example, conductive pads, conductive pillars, or the like. In some embodiments, the electronic die 122 may have a thickness between about 10 μm and about 35 μm. Other thicknesses are possible.

The electronic die 122 may include integrated circuits for interfacing with the photonic components 106, such as circuits for controlling the operation of the photonic components 106. For example, the electronic die 122 may include controllers, drivers, transimpedance amplifiers, the like, or combinations thereof. The electronic die 122 may also include a CPU. In some embodiments, the electronic die 122 includes circuits for processing electrical signals received from photonic components 106, such as for processing electrical signals received from a photonic component 106 comprising a photodetector. The electronic die 122 may control high-frequency signaling of the photonic components 106 according to electrical signals (digital or analog) received from another device or die, in some embodiments. In some embodiments, the electronic die 122 may be an electronic integrated circuit (EIC) or the like that provides Serializer/Deserializer (SerDes) functionality. In this manner, the electronic die 122 may act as part of an I/O interface between optical signals and electrical signals within a photonic package 100, and the photonic package 100 described herein could be considered a system-on-chip (SoC) device or a system-on-integrated-circuit (SoIC) device.

In some embodiments, the electronic die 122 is bonded to the redistribution structure 120 by dielectric-to-dielectric bonding and/or metal-to-metal bonding (e.g., direct bonding, fusion bonding, oxide-to-oxide bonding, hybrid bonding, or the like). In such embodiments, covalent bonds may be formed between oxide layers, such as the topmost dielectric layer 117 and surface dielectric layers (not separately indicated) of the electronic die 122. During the bonding, metal-to-metal bonding may also occur between the die connectors 124 of the electronic die 122 and the conductive pads 116 of the redistribution structure 120.

In some embodiments, before performing the dielectric-to-dielectric bonding and/or metal-to-metal bonding process, a surface treatment is performed on the electronic die 122. In some embodiments, the top surfaces of the redistribution structure 120 and/or the electronic die 122 may first be activated utilizing, for example, a dry treatment, a wet treatment, a plasma treatment, exposure to an inert gas, exposure to H₂, exposure to N₂, exposure to O₂, the like, or combinations thereof. However, any suitable activation process may be utilized. After the activation process, the redistribution structure 120 and/or the electronic die 122 may be cleaned using, e.g., a chemical rinse. The electronic die 122 is then aligned with the redistribution structure 120 and placed into physical contact with the redistribution structure 120. The electronic die 122 may be placed on the redistribution structure 120 using a pick-and-place process, for example. The redistribution structure 120 and the electronic die 122 may then be subjected to a thermal treatment and/or pressed against each other (e.g., by applying contact pressure) to bond the redistribution structure 120 and the electronic die 122. For example, the redistribution structure 120 and the electronic die 122 may be subjected to a pressure of about 200 kPa or less, and to a temperature between about 200° C. and about 400° C. The redistribution structure 120 and the electronic die 122 may then be subjected to a temperature at or above the eutectic point of the material of the conductive pads 116 and the die connectors 124 (e.g., between about 150° C. and about 650° C.) to fuse the conductive pads 116 and the die connectors 124. In this manner, the dielectric-to-dielectric bonding and/or metal-to-metal bonding of the redistribution structure 120 and the electronic die 122 forms a bonded structure. In some embodiments, the bonded structure is baked, annealed, pressed, or otherwise treated to strengthen or finalize the bonds. In other embodiments, the electronic die 122 may be bonded to the redistribution structure 120 using solder bonding, solder bumps, or the like.

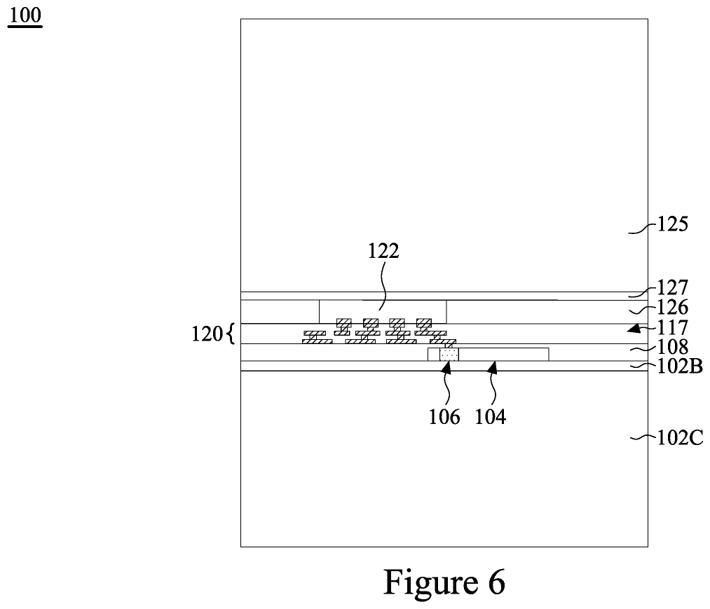

In FIG. 6, a dielectric material 126 is formed over the electronic die 122 and the redistribution structure 120, in accordance with some embodiments. The dielectric material 126 may be formed of silicon oxide, silicon nitride, a polymer, the like, or a combination thereof. The dielectric material 126 may be formed by CVD, PVD, ALD, a spin-on-dielectric process, the like, or a combination thereof. In some embodiments, the dielectric material 126 may be formed by HDP-CVD, FCVD, the like, or a combination thereof. The dielectric material 126 may be a gap-filling material in some embodiments, which may include one or more of the example materials above. Other dielectric materials formed by any acceptable process may be used. The dielectric material 126 may be planarized using a planarization process such as a CMP process, a grinding process, or the like. In some embodiments, the planarization process may expose the electronic die 122 such that a surface of the electronic die 122 and a surface of the dielectric material 126 are substantially coplanar.

Further in FIG. 6, an optional support 125 is attached to the structure, in accordance with some embodiments. The support 125 is a rigid structure that is attached to the structure in order to provide structural or mechanical stability. The use of a support 125 can reduce warping or bending, which can improve the performance of the optical structures such as the waveguides 104 or photonic components 106. The support 125 may comprise one or more materials such as silicon (e.g., a silicon wafer, bulk silicon, or the like), silicon oxide, silicon oxynitride, silicon carbonitride, a metal, an organic core material, the like, or another type of material. The support 125 may be attached to the structure (e.g., to the dielectric material 126 and/or the electronic dies 122) using an adhesive layer 127, as shown in FIG. 6. In other embodiments, the support 125 may be attached using direct bonding (e.g., dielectric-to-dielectric bonding or fusion bonding) or another suitable technique. In some embodiments, the support 125 may have a thickness between about between about 500 μm and about 700 μm. Other thicknesses are possible. The support 125 may also have lateral dimensions (e.g., length, width, and/or area) that are greater than, about the same as, or smaller than those of the structure. In other embodiments, the support 125 is attached at a later process step during the manufacturing of the photonic package 100 than shown. In some embodiments, the support 125 may be subsequently thinned using a CMP process, grinding process, or the like.

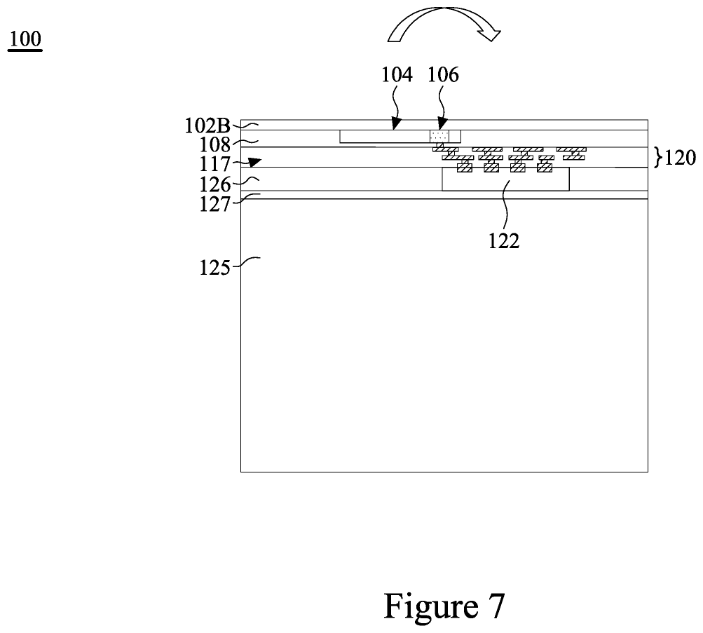

In FIG. 7, the structure is flipped over and the substrate 102C is removed, in accordance with some embodiments. The structure may be attached to a carrier (not shown) prior to removal of the substrate 102C, in some cases. The back side of the substrate 102C is may be removed to expose the oxide layer 102B, in accordance with some embodiments. The substrate 102C may be removed using a CMP process, a mechanical grinding, an etching process, the like, or a combination thereof. In some embodiments, the oxide layer 102B is thinned during removal of the substrate 102C or using a separate process step.

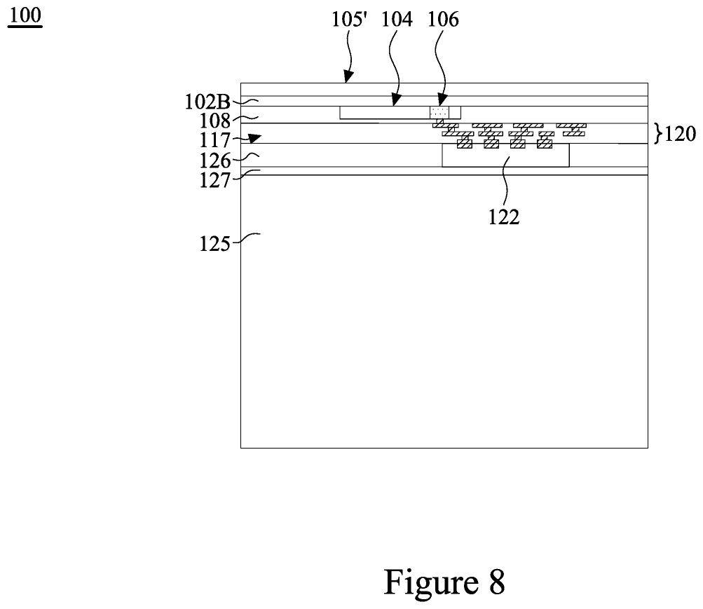

FIGS. 8, 9, and 10 illustrate the formation of waveguides 105 over the oxide layer 102B, in accordance with some embodiments. The waveguides 105 may provide additional routing of optical signals, and may include one or more edge couplers 107 for interfacing with external optical components, described in greater detail below. The waveguides 105 may be optically coupled to one or more waveguides 104 and/or one or more photonic components 106. For example, a waveguide 105 may be evanescently coupled to a waveguide 104 through the oxide layer 102B, though other coupling techniques are possible. In some cases, forming additional waveguides 105 on the oxide layer 102B rather than on the dielectric layer 108 may allow for improved formation of waveguides 105, improved optical coupling to the waveguides 104, reduced optical loss, and increased efficiency.

In FIG. 8, a waveguide material 105′ is deposited over the oxide layer 102B, in accordance with some embodiments. The waveguide material 105′ may be a material similar to or different than the material of the waveguides 104. For example, the waveguide material 105′ may be a material such as silicon, silicon nitride, or the like. The waveguide material 105′ may be deposited using a suitable technique, such as CVD, PVD, ALD, or the like.

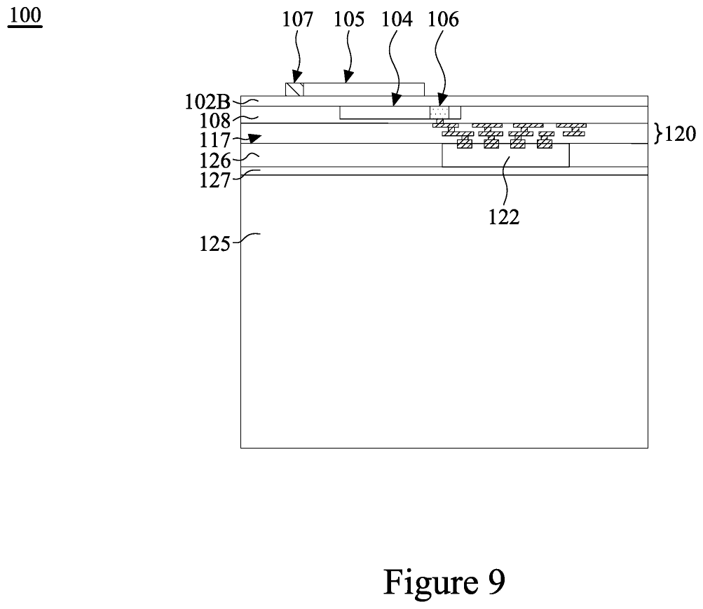

In FIG. 9, the waveguide material 105′ is patterned to form waveguides 105, in accordance with some embodiments. The waveguide material 105′ may be patterned using suitable photolithography and etching techniques. For example, a hardmask layer (e.g., a nitride layer or other dielectric material, not shown in FIG. 9) may be formed over the waveguide material 105′ and patterned, in some embodiments. The pattern of the hardmask layer may then be transferred to the waveguide material 105′ using one or more etching techniques, such as dry etching and/or wet etching techniques. For example, the waveguide material 105′ may be etched to form recesses defining the waveguides 105, with sidewalls of the remaining unrecessed portions defining sidewalls of the waveguides 105. In some embodiments, more than one photolithography and etching sequence may be used in order to pattern the waveguide material 105′. One waveguide 105 or multiple waveguides 105 may be patterned from the waveguide material 105′. If multiple waveguides 105 are formed, the multiple waveguides 105 may be individual separate waveguides 105 or connected as a single continuous structure. In some embodiments, one or more of the waveguides 105 form a continuous loop. Other configurations or arrangements of waveguides 105.

In some embodiments, one or more couplers 107 may be integrated with the waveguides 105, and may be formed with the waveguides 105. The couplers 107 may be continuous with the waveguides 105 and may be formed in the same processing steps as the waveguides 105. The couplers 107 are photonic structures that allow optical signals and/or optical power to be transferred between the waveguides 105 and an external optical component such as an optical fiber or a waveguide of another photonic system. The couplers 107 may include one or more edge couplers, such as the edge coupler 107 shown in FIG. 9. Accordingly, a coupler 107 may also be referred to herein as an edge coupler 107 when appropriate. An edge coupler 107 allows optical signals and/or optical power to be transferred between a waveguide 105 and an optical or photonic component that is “edge-mounted” near a sidewall of the photonic package 100, such as another waveguide, another photonic package, an optical fiber, an external laser diode, or the like. In other embodiments, the couplers 107 include grating couplers, which allow optical signals and/or optical power to be transferred between a waveguide 105 and an optical or photonic component above or below that waveguide 105, such as an optical fiber, a photodetector, another waveguide, or the like.

A photonic package 100 may include a single coupler 107, multiple couplers 107, or multiple types of couplers 107, in some embodiments. The couplers 107 may be formed using acceptable photolithography and etching techniques. In some embodiments, the couplers 107 are formed using the same photolithography or etching steps as the waveguides 105. In other embodiments, the couplers 107 are formed after the waveguides 105.

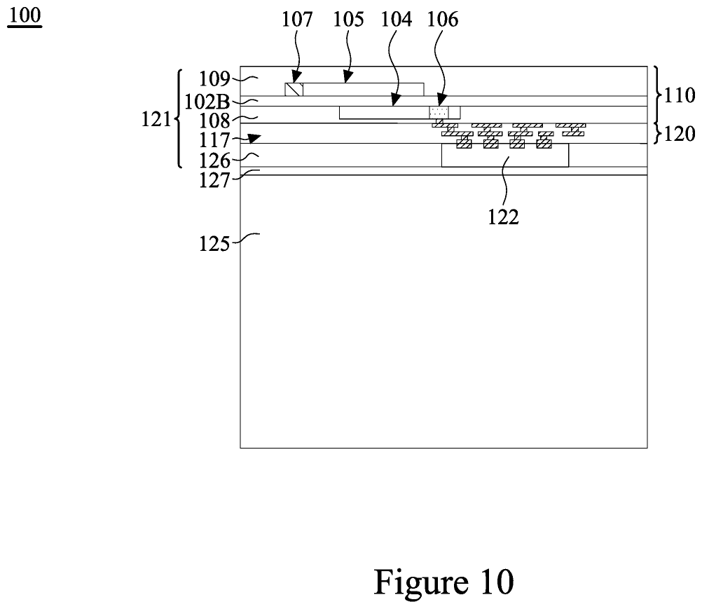

In FIG. 10, a dielectric layer 109 is formed over the waveguides 105 and the oxide layer 102B, in accordance with some embodiments. The dielectric layer 109 may be formed of one or more layers of silicon oxide, silicon nitride, a combination thereof, or the like, and may be formed by CVD, PVD, ALD, a spin-on-dielectric process, the like, or a combination thereof. In some embodiments, the dielectric layer 109 comprises a material similar to that of the oxide layer 102B and/or the dielectric layer 108. Other dielectric materials formed by any acceptable process may be used. In some embodiments, the dielectric layer 109 is then planarized using a planarization process such as a CMP process, a grinding process, or the like.

FIGS. 8-10 illustrate the formation of one layer of waveguides 105 within one dielectric layer log, but in other embodiments multiple layers of waveguides 105 may be formed within multiple dielectric layers log. For example, in some embodiments, multiple layers of silicon nitride waveguides 105 are formed in multiple respective layers of silicon oxide dielectric layers log, though other materials are possible in other embodiments. The multiple layers of waveguides 105 may be formed by repeating techniques described for forming a single layer of waveguides 105. In such embodiments, different layers of waveguides 105 may be optically coupled to each other using evanescent coupling or the like. In other embodiments, one or more edge couplers 107 may be formed in any appropriate layers of waveguides 105. In some cases, the dielectric layer 109 or the topmost dielectric layer 109 may comprise a material suitable for dielectric-to-dielectric bonding, and may thus be considered a “bonding layer.” In some cases, the waveguides 104, waveguides 105, photonic components 106, and edge couplers 107 may collectively be referred to here as the photonic routing structure 110. In this manner a photonic routing structure 110 may be formed on a redistribution structure 120. In some cases, the dielectric material 126, the dielectric layers 117 of the redistribution structure 120, the dielectric layer 108, the oxide layer 102B, and the dielectric layer(s) 109 may be collectively referred to herein as the dielectric layers 121.

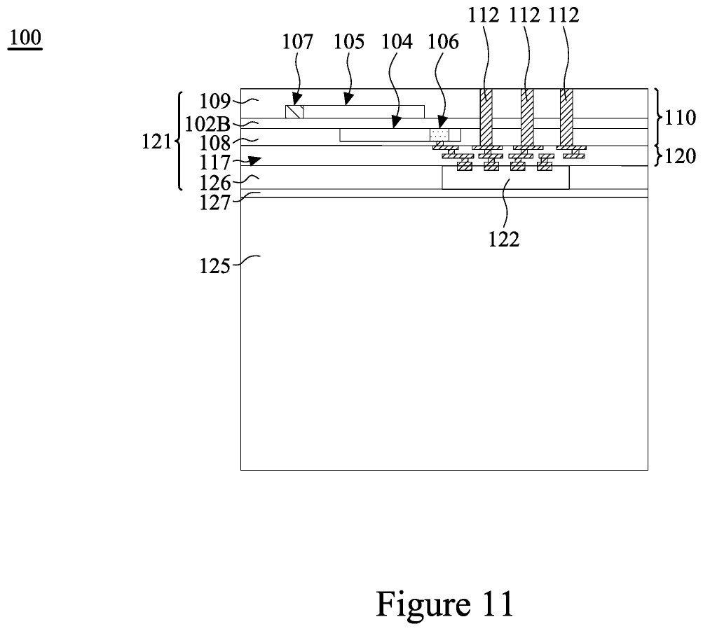

In FIG. 11, vias 112 are formed extending through the photonic routing structure 110 to electrically contact the redistribution structure 120, in accordance with some embodiments. The vias 112 may be formed, for example, by forming openings (not separately shown) extending through the dielectric layer(s) log, the oxide layer 102B, and the dielectric layer 108. The openings may be formed by acceptable photolithography and etching techniques, such as by forming and patterning a photoresist and then performing an etching process using the patterned photoresist as an etching mask. The etching process may include, for example, a dry etching process and/or a wet etching process. The openings may expose conductive features of the redistribution structure 120.

Conductive material is then deposited in the openings, thereby forming vias 112, in accordance with some embodiments. In some embodiments, a liner (not shown), such as a diffusion barrier layer, an adhesion layer, or the like, may be deposited in the openings from tantalum nitride, tantalum, titanium nitride, titanium, cobalt tungsten, or the like, and may be formed using a suitable deposition process such as ALD or the like. In some embodiments, a seed layer (not shown), which may include copper or a copper alloy, may then be deposited in the openings. The conductive material of the vias 112 is then formed in the openings using, for example, ECP or electro-less plating. The conductive material may include, for example, a metal or a metal alloy such as copper, silver, gold, tungsten, cobalt, aluminum, ruthenium, alloys thereof, or the like. A planarization process (e.g., a CMP process or a grinding process) may be performed to remove excess conductive material along the top surface of the dielectric layer(s) log, such that top surfaces of the vias 112 and the dielectric layer(s) 109 are level. The vias 112 may be formed using any other suitable process, such as by a damascene process (e.g., single damascene or dual damascene), the like, or another process. More or fewer vias 112 may be formed than shown, and in other embodiments no vias 112 are formed. In other embodiments, the vias 112 may be formed at a different step in the manufacturing process than shown.

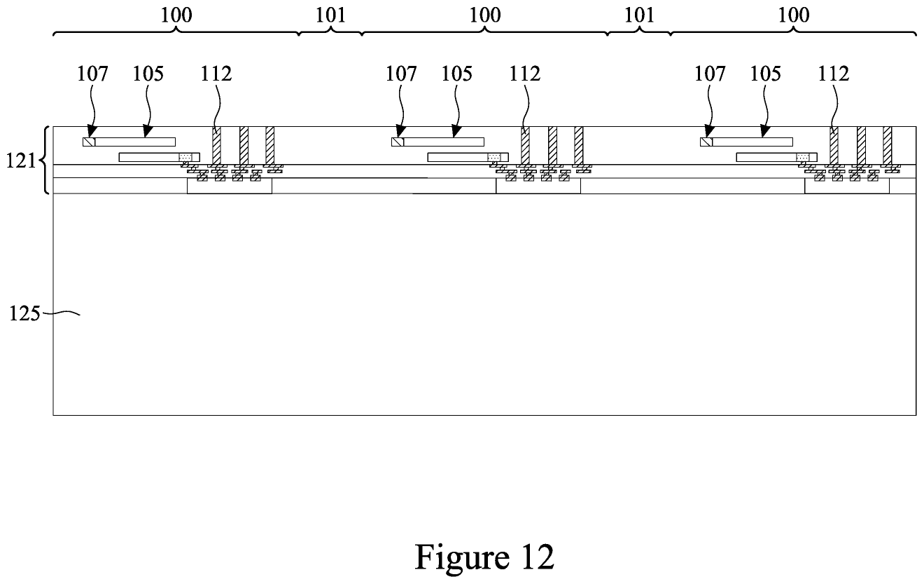

FIGS. 12 through 15 illustrate intermediate steps in the singulation of multiple photonic packages 100 formed on the substrate 102 into individual photonic packages 100, in accordance with some embodiments. FIG. 12 illustrates multiple photonic packages 100 similar to the photonic package 100, except FIG. 12 shows the photonic packages 100 before singulation. For example, the multiple photonic packages 100 of FIG. 12 may be formed concurrently on the same substrate 102 with scribe regions 101 between neighboring photonic packages 100. The scribe regions 101 are subsequently removed to singulate the photonic packages 100 into individuals. For clarity reasons, FIGS. 12 through 15 do not show all of the features or labels shown in FIG. 11. The relative sizes of various features may also be different than FIG. 11 for clarity reasons.

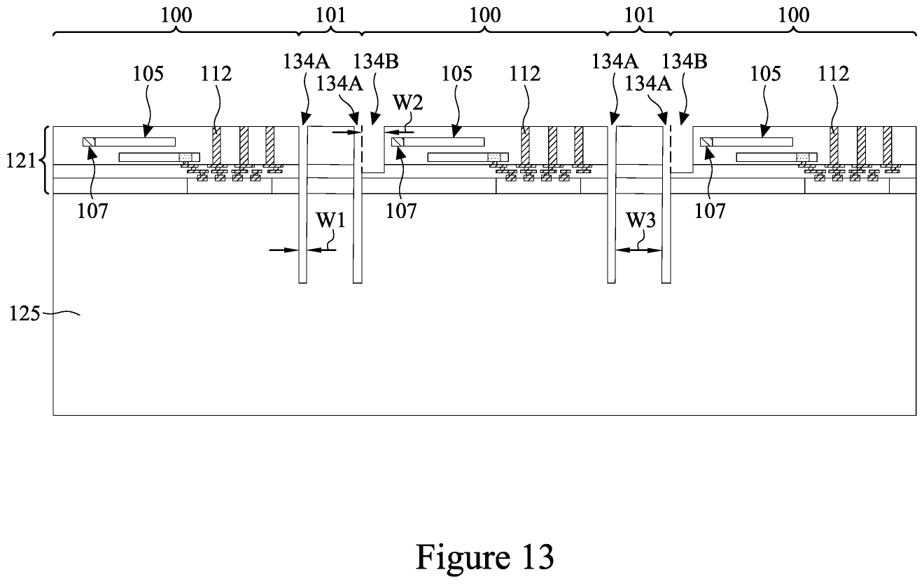

In FIG. 13, recesses 134A and optional recesses 134B are formed in the back side of the structure, in accordance with some embodiments. The recesses 134 (e.g., the recesses 134A and 134B) may be formed using one or more etching processes. For example, an etching mask may be formed over the back side of the dielectric layers 121 (e.g., the side facing up in FIG. 13) using suitable photolithography techniques, and then one or more etching processes may be performed using the etching mask. In some embodiments, the etching process comprises an anisotropic dry etch, such as a plasma etch. In this manner, the etching process may be considered a “plasma dicing process” in some cases. The etching process may comprise one or more different dry etching steps, which may use similar or different processes. For example, different materials may be etched using different process gases or etching parameters. In some cases, the etching process comprises a plurality of etching cycles. For example, an etching cycle may include an etching step to extend the recesses 134 followed by depositing a passivation material or polymer on sidewalls of the recesses 134.

As shown in FIG. 13, the etching process forms recesses 134A extending through the dielectric layers 121 and into the support 125. In some embodiments, a recess 134A may be formed on each side of a scribe region 101 such that each scribe region 101 has a corresponding pair of recesses 134A. In some embodiments, a sidewall surface of some recesses 134A are adjacent a waveguide 104, a waveguide 105, and/or an edge coupler 107 of the photonic packages 100. In some embodiments, the recesses 134A may have a width W1 in the range of about 5 μm to about 30 μm. In some embodiments, a pair of recesses 134A of a scribe region 101 may be separated by a width W3 that is in the range of about 40 μm to about 400 μm, though other widths are possible. The sidewalls of the recesses 134 may be substantially vertical, tapered, convex, concave, or irregular. In some embodiments, the recesses 134A may have a depth in the range of about 50 μm to about 200 μm. In some embodiments, the recesses 134 may extend into the support 125 a depth that is in the range of about 40 μm to about 190 μm. Other depths or widths are possible.

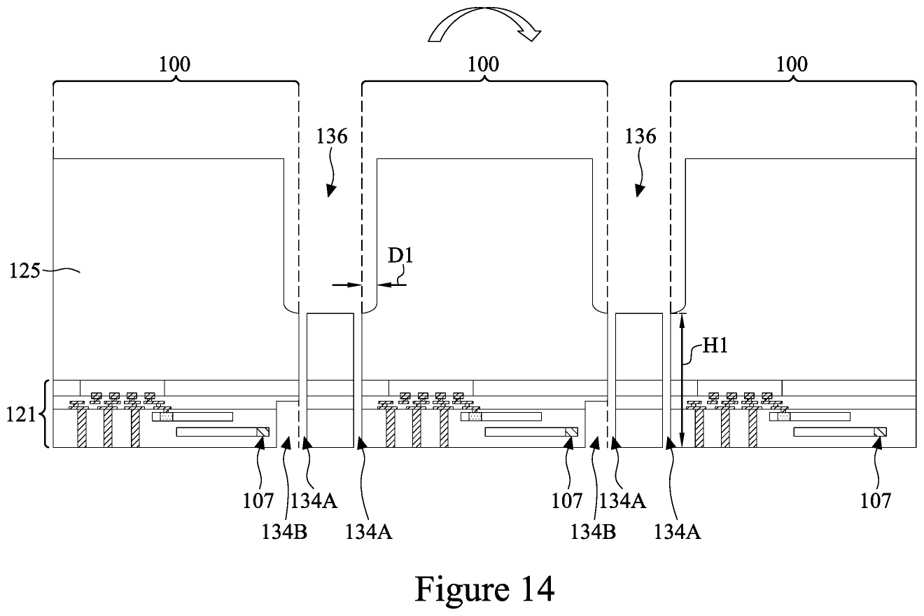

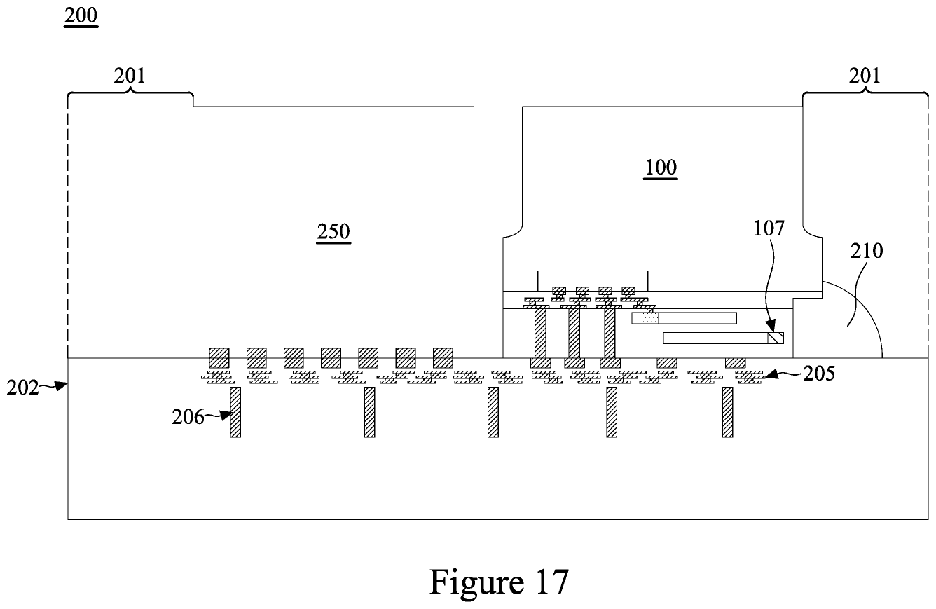

In some embodiments, optional recesses 134B are also formed between a recess 134A and an edge coupler 107 of a photonic package 100. The recesses 134B may be, for example, a vertical trench that laterally extends a portion of a recess 134A toward the edge coupler 107. In other words, the recess 134B reduces the lateral width of the dielectric layers 121 between the edge coupler 107 and a sidewall of the photonic package 100. In some embodiments, a width W2 of a recess 134B, corresponding to an offset between a sidewall of the recess 134B and a sidewall of the corresponding recess 134B, is in the range of about 0 μm to about 10 μm, though other widths are possible. In some cases, reducing the lateral width between an edge coupler 107 and a sidewall of the photonic package 100 can improve optical coupling between the edge coupler 107 and e.g., an edge-mounted external fiber. In some embodiments, the lateral width between an edge coupler 107 and a sidewall of a recess 134B may be in the range of about 0 μm to about 3 μm, though other widths are possible. In some embodiments, the recess 134B allows a protective material (e.g., protective material 210 shown in FIG. 17) to be formed over the sidewall of the photonic package 100 that protects the sidewall from damage during subsequent processing. In some embodiments, the recess 134B offsets the sidewall adjacent an edge coupler 107 such that there is less risk of damage to the sidewall during a subsequent sawing process (see FIG. 14). The recesses 134B may be formed using a separate etching masking and/or etching step, in some embodiments. A recess 134B may be formed on more than one side of the photonic package 100, and each recess 134B may be near one or more edge couplers 107, in some embodiments. In other embodiments, the recesses 134B are not formed.

In some cases, a dry anisotropic etch (e.g. a plasma etch) can remove portions of the scribe regions 101 with less cracking, chipping, or thermal damage than other singulation techniques such as mechanical sawing. The use of a dry anisotropic etch for singulation can also form smoother sidewall surfaces (e.g. of the recesses 134A-B). In some cases, a smoother sidewall surface near a waveguide or edge coupler can allow for improved optical coupling to that waveguide or edge coupler, which can allow for improved efficiency, less signal loss, and less power consumption. In this manner, the use of a dry anisotropic etch during singulation as described herein can allow for improved performance of the singulated devices.

The recesses 134A-B extend from a back surface of the structure (e.g. a back side surface of the substrate 102C) toward a front surface of the structure (e.g., a front side surface of the support 125). Accordingly, the recesses 134A-B may be subsequently referred to as “bottom recesses 134.” As shown in FIG. 13, the bottom recesses 134 extend incompletely through the structure (e.g. only partway into the support 125), and a portion of the support 125 remains under the bottom recesses 134 (in the orientation shown in FIG. 13). The recesses 134A may extend into the support 125, and the recesses 134B may extend into the dielectric layers 121 or through the dielectric layers 121 into the support 125.

In FIG. 14, the structure is flipped over, and a sawing process is performed on the front side of the structure, in accordance with some embodiments. The sawing process may be, for example, a mechanical sawing or dicing process using one or more blades. As shown in FIG. 14, the sawing process forms recesses 136 that extend from a front surface of the structure (e.g., a front side surface of the support 125) toward a back surface of the structure (e.g. a back side surface of the substrate 102C). Accordingly, the recesses 136 may be subsequently referred to as “top recesses 136.” The top recesses 136 may be aligned with the scribe regions 101 such that each top recess 136 overlaps a pair of bottom recesses 134 of a scribe region 101. The top recesses 136 shown in FIG. 14 are examples, and top recesses 136 may have different shapes, sizes, or relative locations in other embodiments.

Each top recess 136 may have a width greater than the width of the underlying pair of recesses 134A (e.g., wider than W3 plus twice W1). In some embodiments, the a sidewall of a top recess 136 may be offset from a sidewall of a recess 134A by a distance D1 that is in the range of about 5 μm to about 50 μm, though other distances are possible. As shown in FIG. 14, the top recesses 136 may extend incompletely through the support 125, but extend deep enough that the bottom recesses 134 are exposed. In other words, the combination of the bottom recesses 134 and the top recesses 136 forms openings that extend completely through the structure. In this manner, forming both the bottom recesses 134 and the top recesses 136 fully removes material between adjacent photonic packages 100, singulating the photonic packages 100 into separate, individual photonic packages 100. After forming the top recesses 136, the remaining sidewalls of the bottom recesses 134 may have a height H1 that is in the range of about 50 μm to about 400 μm, though other heights are possible.

Top recesses 136 and/or bottom recesses 134 may be formed on a single side of a photonic package 100, all sides of a photonic package 100, or on only some of the sides of a photonic package 100. Using a combination of forming bottom recesses 134 using plasma dicing and forming top recesses 136 using sawing allows for singulation of photonic structures 100 with reduced damage and improved sidewall surface quality near edge-coupled waveguides, which can improve the optical coupling efficiency to the waveguides. In FIG. 15, the singulated photonic packages 100 are removed and placed on a tape 132 or other supporting structure, in accordance with some embodiments. In some cases, the singulated photonic packages 100 may be considered “reconstructed wafers.”

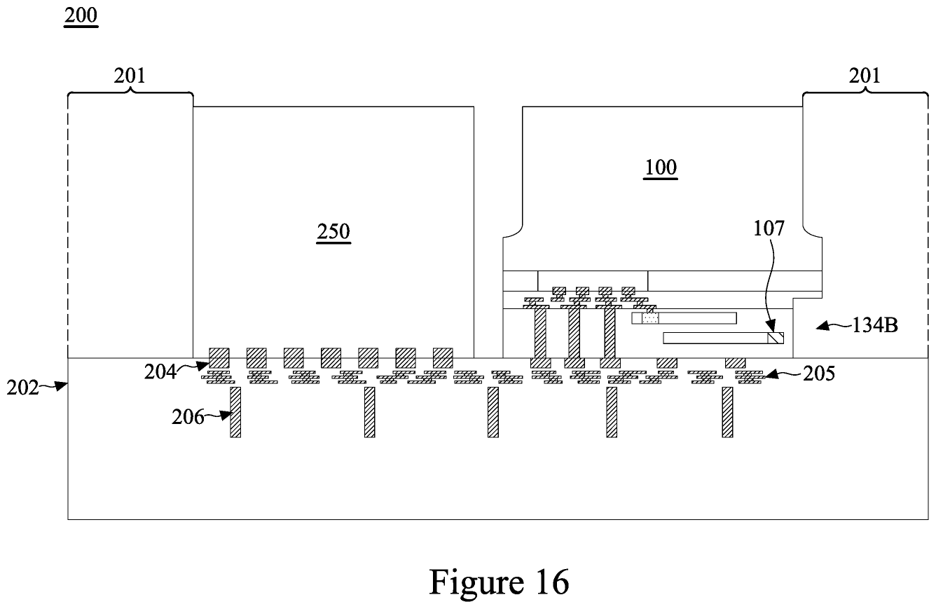

FIGS. 16 through 18 illustrate the formation of a photonic structure 200, in accordance with some embodiments. The photonic structure 200 comprises at least one photonic package 100 and at least one semiconductor device 250 connected to an interconnect structure 202, in some embodiments. In some embodiments, multiple photonic structures 200 are formed on the same interconnect structure 202 and then singulated to form individual photonic structures 200. In this manner, scribe regions 201 may separate the photonic structures 200 before singulation. The photonic package 100 may be similar to the photonic package 100 described in FIGS. 1-15, in some embodiments. The photonic package 100 shown in FIG. 16 includes a recess 134B, but in other embodiments no recess 134B is present.

The semiconductor device(s) 250 of the photonic structure 200 may be, for example, semiconductor devices, chips, dies, system-on-chip (SoC) devices, system-on-integrated-circuit (SoIC) devices, other packages, the like, or a combination thereof. The semiconductor device(s) 250 may include one or more processing devices, such as a central processing unit (CPU), a graphics processing unit (GPU), an application-specific integrated circuit (ASIC), a high performance computing (HPC) die, the like, or a combination thereof. The semiconductor device(s) 250 may include one or more memory devices, which may be a volatile memory such as dynamic random-access memory (DRAM), static random-access memory (SRAM), high-bandwidth memory (HBM), another type of memory, or the like. Other types of semiconductor devices or combinations of semiconductor devices are possible.

In some embodiments, the interconnect structure 202 comprises conductive pads 204, conductive routing 205, and through substrate vias (TSVs) 206. The conductive routing 205 may provide electrical interconnections and may electrically couple the conductive pads 204 and the TSVs 206, in some embodiments. The conductive routing 205 may comprise one or more layers of conductive lines, conductive vias, redistribution layers, metallization patterns, or the like. In some cases, the interconnect structure 202 may comprise an interposer, a semiconductor substrate, redistribution structure, a core substrate, or a different type of structure than these examples. In some embodiments, the interconnect structure 202 comprises active and/or passive devices. In other embodiments, the interconnect structure 202 is free of active and/or passive devices.

In some embodiments, the photonic package 100 and the semiconductor device 250 are bonded to the interconnect structure 202 by dielectric-to-dielectric bonding and/or metal-to-metal bonding (e.g., direct bonding, fusion bonding, oxide-to-oxide bonding, hybrid bonding, or the like). In such embodiments, covalent bonds may be formed between oxide layers, such as the topmost dielectric layer of the interconnect structure 202 and surface dielectric layers (not separately indicated) of the photonic package 100 and/or the semiconductor device 250. During the bonding, metal-to-metal bonding may also occur between conductive pads of the semiconductor device 250 and conductive pads 204 of the interconnect structure 202, and metal-to-metal bonding may occur between vias 112 or conductive pads (if present) of the photonic package 100 and conductive pads 204 of the interconnect structure 404. The bonding process may be similar to the bonding process described previously for the electronic die 122 (see FIG. 8). In this manner, the photonic package 100 and the semiconductor device 250 may be electrically coupled to the conductive routing 205 and/or the TSVs 206.

In FIG. 17, a protective material 210 is deposited on a sidewall of the photonic package 100 adjacent an edge coupler 107, in accordance with some embodiments. The protective material 210 may extend on the interconnect structure 202 and may fill the recess 134B, if present. In this manner, the sidewall adjacent the edge coupler 107 may be protected during subsequent processing steps, such as structure singulation (see FIGS. 19-20). Protecting the sidewall adjacent an edge coupler 107 can result in improved optical coupling to that edge coupler 107, in some cases. The protective material 210 is subsequently removed using a suitable process, such as a wet cleaning process. Thus, the protective material 210 may be considered a sacrificial material or a temporary layer in some cases. In some embodiments, the protective material 210 comprises a material such as a polymer that is soluble in water or an organic solvent, though other materials are possible. The protective material 210 may be deposited or dispensed using any suitable technique. As shown in FIG. 17, in some embodiments, the protective material 210 is deposited on sidewalls adjacent an edge coupler 107 and/or adjacent a scribe region 201. In other embodiments, the protective material 210 is deposited on other surfaces in addition to these.

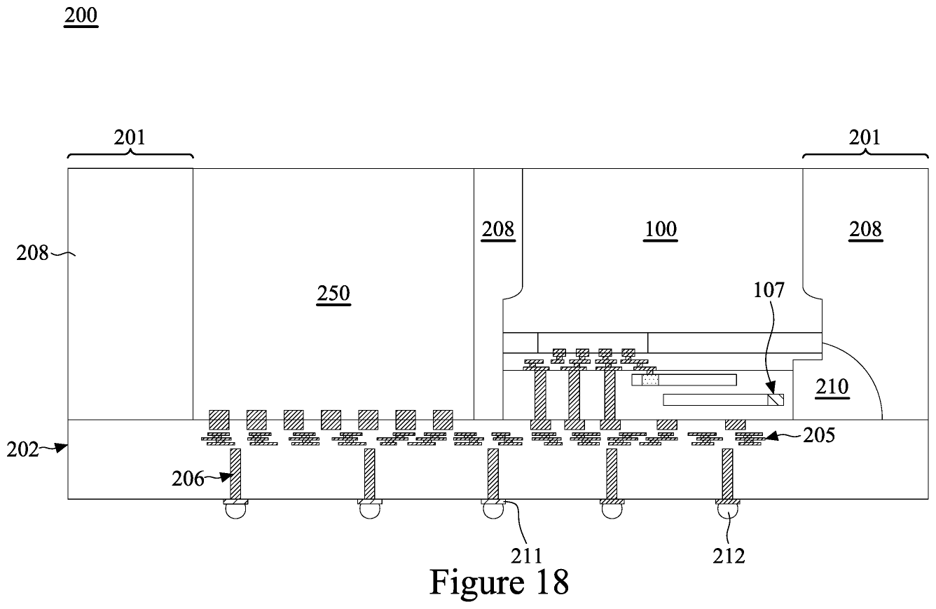

In FIG. 18, an encapsulant 208 is formed on the interconnect structure 202 and around the various components. For example, the encapsulant 208 may encapsulate the photonic package 100 and the semiconductor device 250. In some embodiments, the protective material 210 covering a sidewall of the photonic package 100 (e.g., covering the recess 134B) blocks the encapsulant 208 from physically contacting that sidewall. The encapsulant 208 is further formed in the gap between the photonic package 100 and the semiconductor device 250. The encapsulant 208 is also formed in the scribe regions 201. The encapsulant 208 may be a molding compound, epoxy, or the like. The encapsulant 208 may be applied by compression molding, transfer molding, or the like. The encapsulant 208 may be applied in liquid or semi-liquid form and then subsequently cured. Other materials or deposition techniques are possible. In some embodiments, a planarization process (e.g., a CMP process, grinding process, or the like) is performed after forming the encapsulant 208. In some embodiments, top surfaces of the photonic package 100 and/or the semiconductor device 250 may be exposed by the planarization process. In some embodiments, after performing the planarization process, top surfaces of the encapsulant 208, the photonic package 100, and/or the semiconductor device 250 may be substantially level or coplanar.

Further in FIG. 18, conductive connectors 212 are formed on the interconnect structure 202, in accordance with some embodiments. The conductive connectors 212 may be formed, for example, by thinning the back side of the interconnect structure 202 to expose the TSVs 206. The thinning may be achieved using a planarization process (e.g., a CMP process, a grinding process), an etching process, or the like. In some embodiments, conductive pads 211 are formed on the exposed TSVs 206 and the conductive connectors 212, and the conductive connectors 212 are formed on the conductive pads 211. The conductive pads 211 and the conductive connectors 212 may be electrically connected to the conductive routing 205 by the TSVs 206.

The conductive pads 211 may be conductive features such as conductive pads, conductive pillars, conductive lines, or the like. In some embodiments, the conductive pads 211 comprise under-bump metallizations (UBMs). The conductive pads 211 may be formed from one or more conductive materials such as copper, aluminum, another metal or metal alloy, the like, or a combination thereof. The conductive material of the conductive pads 211 may be formed using a suitable process, such as sputtering, printing, electro plating, electroless plating, CVD, or the like. In some embodiments, the conductive pads 211 comprise metal pillars (e.g., copper pillars or the like), which may be solder free and have substantially vertical sidewalls. In some embodiments, a metal cap layer (not shown) is formed on the conductive pads 211. The metal cap layer may include nickel, tin, tin-lead, gold, silver, palladium, indium, nickel-palladium-gold, nickel-gold, the like, or a combination thereof and may be formed by a plating process. In some embodiments, a passivation layer (not shown) may be formed over the back side of the interconnect structure 202 to surround or partially cover the conductive pads 211. The passivation layer may comprise a dielectric material such as silicon oxide, silicon nitride, or the like. Other materials or techniques are possible. In other embodiments, conductive pads 211 are not formed.

Still referring to FIG. 18, conductive connectors 212 may be formed on the conductive pads 211, in accordance with some embodiments. The conductive connectors 212 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 212 may include a conductive material such as solder, copper, aluminum, gold, nickel, silver, palladium, tin, the like, or a combination thereof. In some embodiments, the conductive connectors 212 are formed by initially forming a layer of solder using a suitable technique such as evaporation, electroplating, printing, solder transfer, ball placement, or the like. Once a layer of solder has been formed on the structure, a reflow may be performed in order to shape the material into the desired bump shapes. In another embodiment, the conductive connectors 212 are metal pillars (such as copper pillars) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 212. The metal cap layer may include nickel, tin, tin-lead, gold, silver, palladium, indium, nickel-palladium-gold, nickel-gold, the like, or a combination thereof and may be formed by a plating process. Other materials or techniques are possible.

In FIG. 19, a singulation process is performed to separate the photonic structures 200 formed on the same interconnect structure 202 into individual photonic structures 200. The singulation process may comprise sawing through the scribe regions 201 using a mechanical saw, in some embodiments. In other embodiments, the conductive connectors 212 may be formed after singulation. In some embodiments, the singulation process exposes the protection material 210 and/or the photonic package 100. For example, the support 125 and/or the dielectric layers 121 of the photonic package 100 may be exposed by the singulation process. In some embodiments, after singulation, sidewalls of the photonic package 100, the protection material 210, the interconnect structure 202, and/or the encapsulant 208 are coplanar. After singulation, the width of the remaining protection material 210 may in the range of about 0 μm to about 8 μm, though other widths are possible.

In other embodiments, sidewalls of the photonic package 100 may remain covered by the encapsulant 208 after performing the singulation process. As an example, FIG. 20 shows a photonic structure 200 in which sidewalls of the photonic package 100 are not exposed by the singulation process. In such embodiments, the width of the remaining protection material 210 may be greater than about 8 μm, though other widths are possible. In some cases, leaving sidewalls of the photonic package 100 covered by the encapsulant 208 can reduce risk of damage to the photonic package 100 during the singulation process or during subsequent processing steps.

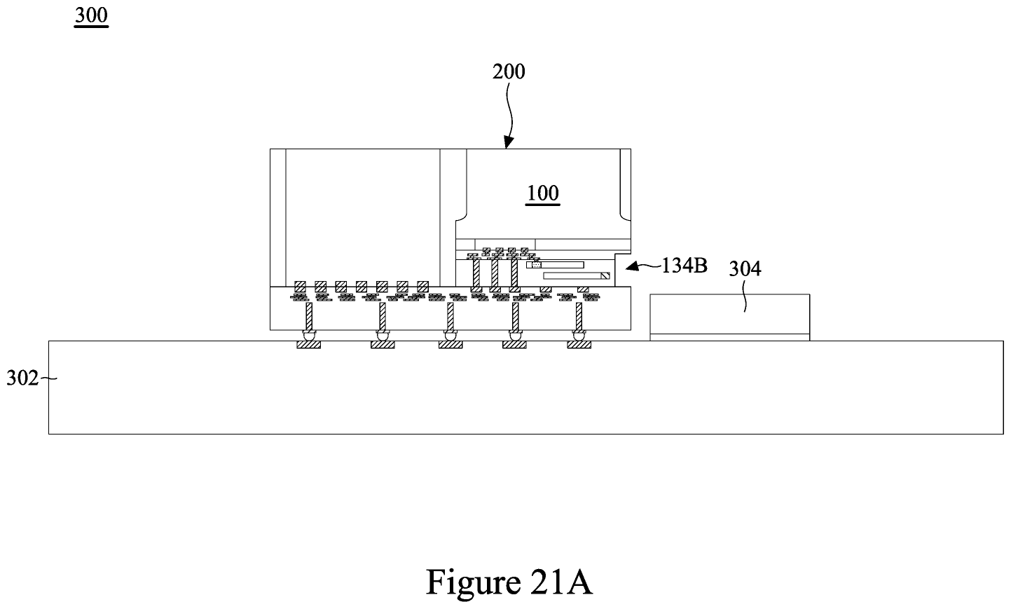

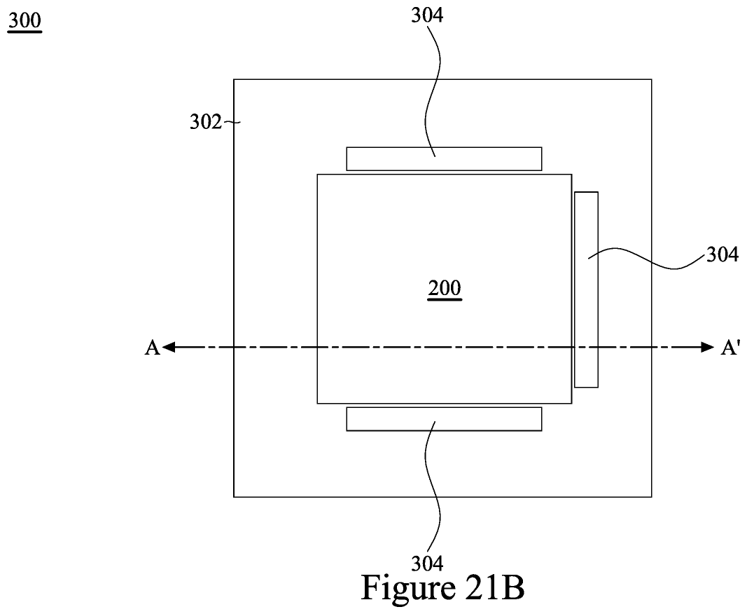

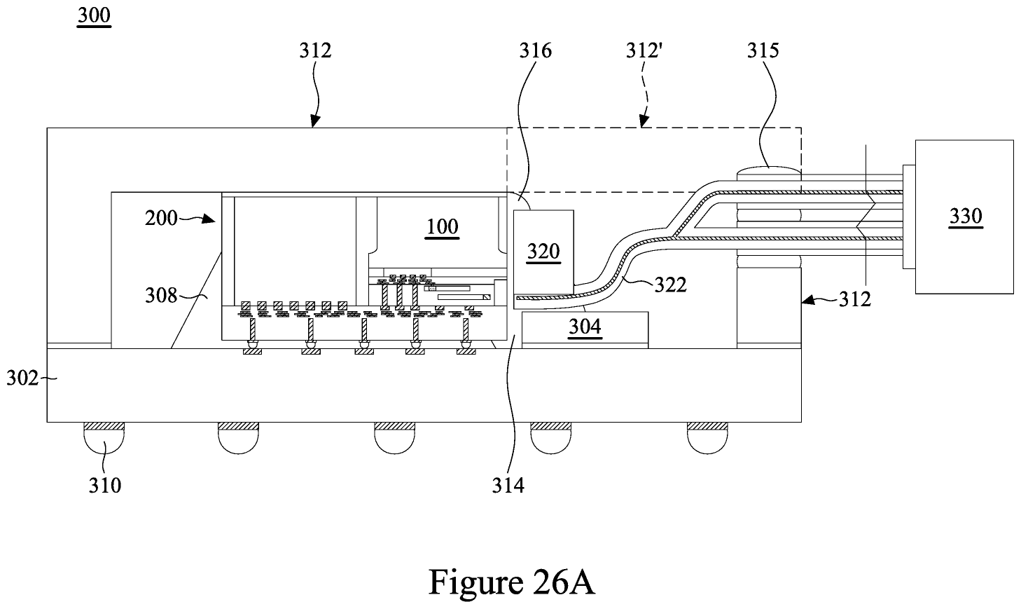

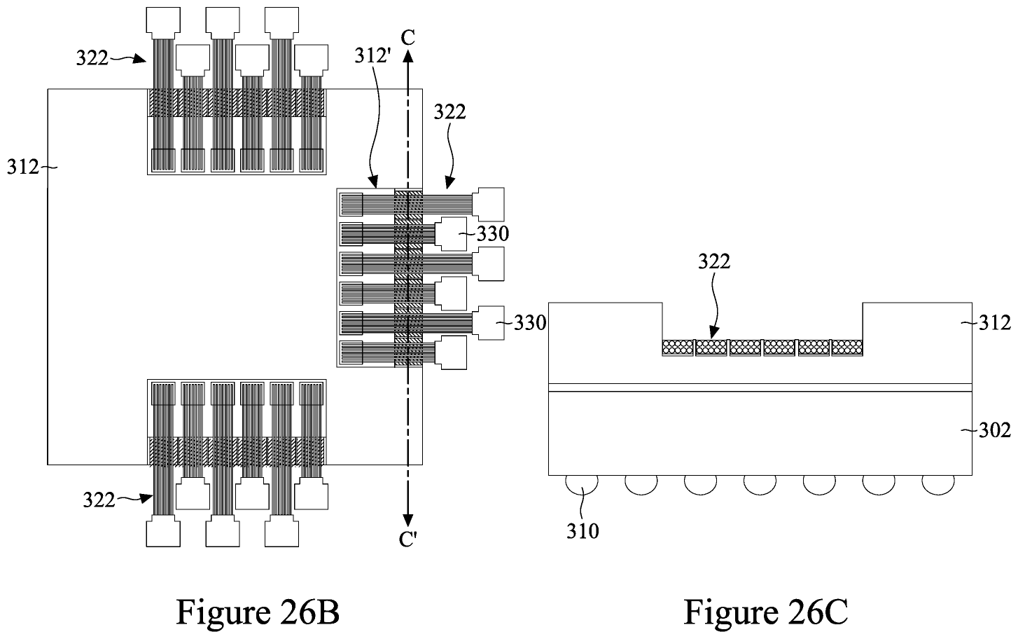

FIGS. 21A through 26E illustrate intermediate steps in the formation of a photonic system 300, in accordance with some embodiments. The photonic system 300 comprises at least one photonic structure 200 that is optically coupled to one or more optical fibers 322 (see FIG. 26A). In this manner, optical signals and/or optical power may be transmitted to or from the photonic structure 200. For example, optical signals may be transmitted from an optical fiber 322 into the photonic structure 200. The optical signals may be processed or analyzed by the photonic structure 200, and the photonic structure 200 may generate and transmit other optical signals to the optical fiber 322. This is an example, and other applications are possible.

In FIGS. 21A and 21B, a photonic structure 200 is attached to an interconnect substrate 302, in accordance with some embodiments. FIG. 21A illustrates a cross-sectional view, and FIG. 21B illustrates a plan view. The cross-section shown in FIG. 21A is indicated by cross-section A-A′ in FIG. 21B. The interconnect substrate 302 may comprise an interposer, a semiconductor substrate, redistribution structure, a core substrate, or a different type of structure than these examples. The interconnect substrate 302 may comprise conductive pads, conductive routing, through vias, or the like. In some embodiments, the interconnect substrate 302 comprises active and/or passive devices. In other embodiments, the interconnect substrate 302 is free of active and/or passive devices.

In some embodiments, the photonic structure 200 is attached to the interconnect substrate 302 by placing the conductive connectors 212 of the photonic structure 200 on conductive pads of the interconnect substrate 302 and performing a reflow process. In this manner, the photonic structure 200 may be physically and electrically coupled to the interconnect substrate 302. In some embodiments, a flux cleaning process may be performed as part of connecting the conductive connectors 212 to the interconnect substrate 302. The flux cleaning process may comprise, for example, a wet chemical process comprising water and surfactants, though other flux cleaning processes are possible.

In some embodiments, the protective material 210 is removed from the photonic structure 200. The protective material 210 may be removed before or after attaching the photonic structure 200 to the interconnect substrate 302. The protective material 210 may be removed, for example, using a wet cleaning process. In some embodiments, the flux cleaning process also removes the protective material 210.

Further in FIGS. 21A-21B, a fiber support 304 is optionally attached to the interconnect substrate 302, in accordance with some embodiments. The fiber support 304 is an optional structure that helps support the subsequently-attached optical fiber 322 (see FIG. 26A). In this manner, a fiber support 304 may be attached near one or more edge couplers 107 of the photonic structure 200, in some embodiments. FIG. 21B illustrates an embodiment in which three fiber supports 304 are attached near three different sides of the photonic structure 200, but in other embodiments fiber supports 304 may be attached near more or fewer sides of a photonic structure 200. Additionally, more or fewer fiber supports 304 may be attached than shown. For example, more than one fiber support 304 may be attached near the same side of the photonic structure 200, in some cases. The fiber supports 304 may have different dimensions or different shapes than shown.

The fiber support 304 may be attached to the interconnect substrate 302 using an adhesive, a Die Attach Film (DAF), a glue, an epoxy, or the like. The fiber support 304 may comprise one or more materials such as silicon (e.g., bulk silicon), silicon oxide, ceramic, glass, polymer, metal, metal alloy, the like, or a combination thereof. The fiber support 304 may have a thickness in the range of about 20 μm to about 100 μm, though other thicknesses are possible. In some embodiments, the fiber support 304 may be laterally separated from the photonic package 100 by a distance in the range of about 50 μm to about 1000 μm, though other distances are possible.

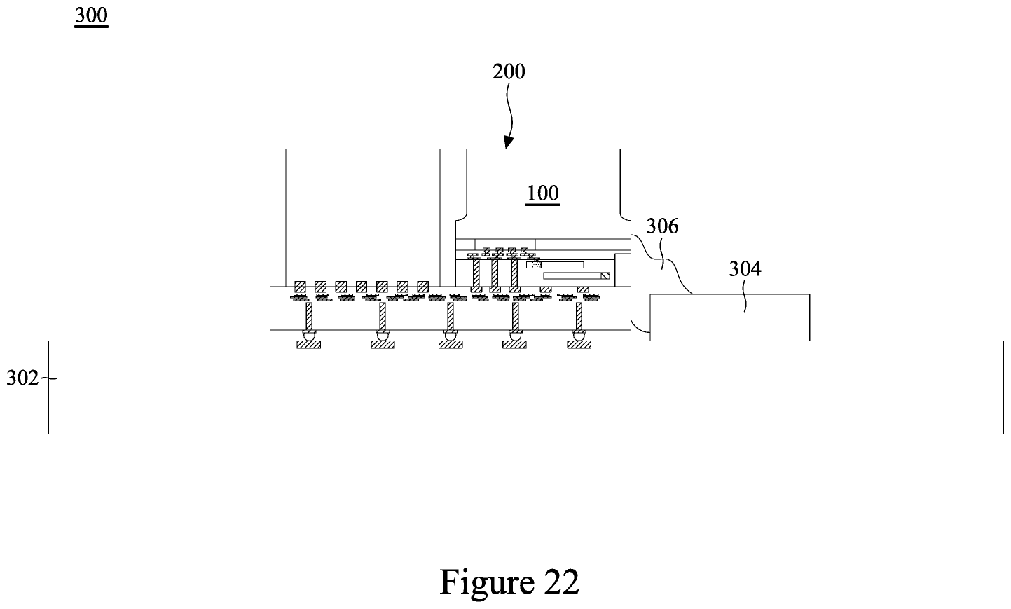

In FIG. 22, a protection material 306 is deposited on a sidewall of the photonic package 100 of the photonic structure 200, in accordance with some embodiments. The protection material 306 may be similar to the protection material 210 (see FIG. 17) and may be deposited using similar techniques. The protection material 306 may be deposited on a sidewall adjacent an edge coupler 107, similar to the protection material 210. In this manner, the protection material 306 may protect the sidewall of the photonic package 100 during subsequent processing steps. In embodiments in which a recess 134B is present, the protection material 306 may fill or partially fill the recess 134B. The protection material 306 may overfill the recess 134B and extend on sidewall surfaces outside of the recess 134B, in some cases. In some embodiments, the protection material 306 may extend from the photonic structure 200 to the fiber support 304, and physically contact a sidewall surface and/or a top surface of the fiber support 304. In other words, the protection material 306 may fill or partially fill the lateral gap between the photonic structure 200 and the fiber support 304. The protection material 306 may physically contact the interconnect substrate 302 or may be separated from the interconnect substrate 302, as shown in FIG. 22. A protection material 306 may be deposited on multiple sidewalls of a photonic structure 200, in some embodiments, such as embodiments in which the photonic structure 200 comprises multiple edge couplers 107 near different sidewalls of the photonic structure 200.

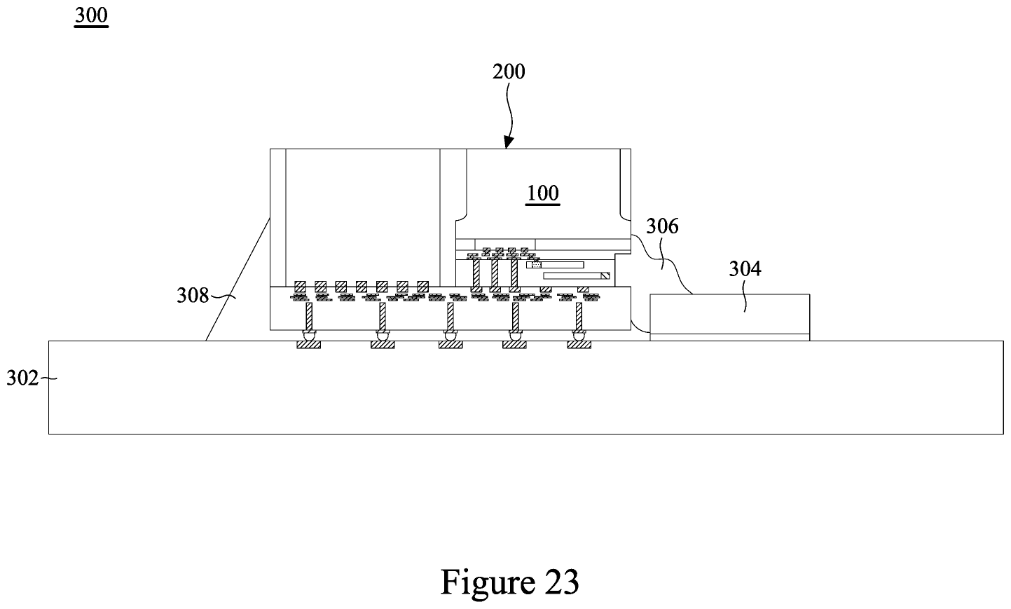

In FIG. 23, an underfill 308 is deposited, in accordance with some embodiments. In some embodiments, the underfill 308 is deposited away from the protection material 306 such that the protection material 306 is not deposited onto top surfaces of the protection material 306. For example, the underfill 308 may be deposited near a sidewall of the photonic structure 200 that is opposite that of the protection material 306. In this manner, the underfill 308 may be deposited such that top surfaces of the protection material 306 are not covered by the underfill 308 and remain exposed. The protection material 306 blocks the underfill 308 from covering the sidewall adjacent the edge coupler 107 (e.g., the sidewall of the recess 134B), in some embodiments. As shown in FIG. 23, the underfill 308 may flow underneath the photonic structure 200 and may surround the conductive connectors 212 of the photonic structure 200, in some cases. In some embodiments, the underfill 308 physically contacts bottom surfaces of the protection material 306. The underfill 308 may cover or partially cover bottom surfaces of the protection material 306, in some cases. The underfill 308 may physically contact the fiber support 304, in some cases. In some cases, the protection material 306 and/or the fiber support 304 are free of the underfill 308. The underfill 308 may be cured after deposition, in some cases.

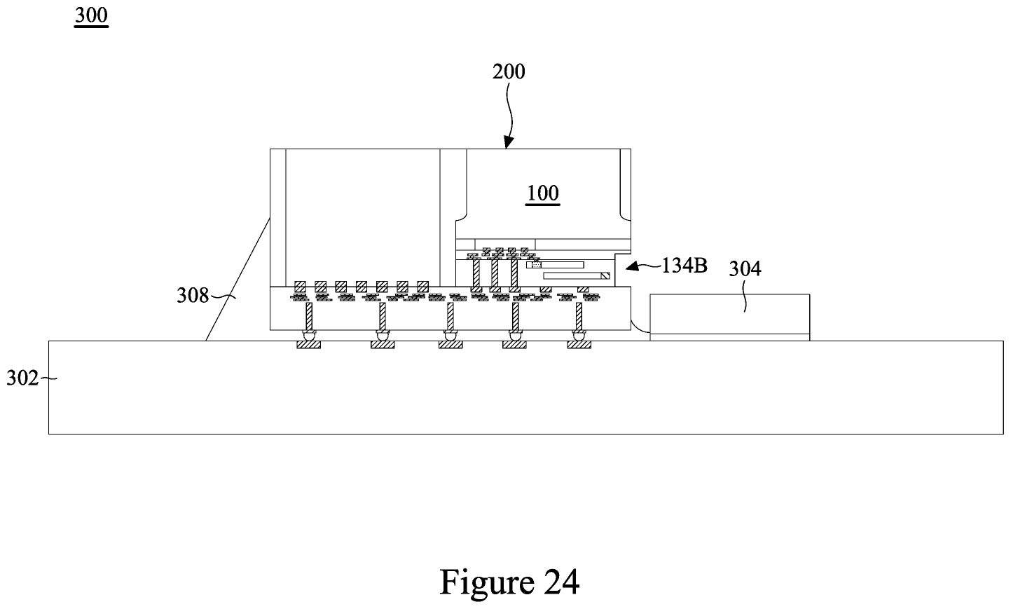

In FIG. 24, the protection material 306 is removed, in accordance with some embodiments. The protection material 306 may be removed using a technique similar to those described earlier or using a different technique. For example, the protection material 306 may be removed using a wet chemical clean such as flux cleaning process, a cleaning process using a solution of surfactants in water, or another suitable process. Removing the protection material 306 exposes sidewalls of the photonic structure 200 near the edge couplers 107, such as sidewalls within the recess(es) 134B.

In FIGS. 25A, 25B, and 25C, a lid 312 is attached to the interconnect substrate 302, in accordance with some embodiments. FIG. 25B illustrates a plan view, similar to FIG. 21B. FIG. 25A illustrates a cross-sectional view along the cross-section A-A′ shown in FIG. 25B, similar to FIG. 21A. FIG. 25C illustrates a cross-sectional view along the cross-section C-C′ shown in FIG. 25B. The lid 312 may comprise a suitable material such as metal, ceramic, polymer, composite, or a combination thereof. The lid 312 may be attached using a suitable technique such as an adhesive, epoxy, glue, or the like. For example, as shown in FIG. 25A, the lid 312 may be attached to the interconnect substrate 302 by an adhesive layer (not separately labeled) and may be attached to the photonic structure 200 by an adhesive layer (not separately labeled). In some embodiments, the lid 312 comprises one or more openings 312′ that allow for the subsequent attachment and coupling of optical fibers (e.g., optical fibers 322 in FIG. 26A). The lid 312 may protect the structure 200 and also may facilitate heat dissipation, in some cases.

Further in FIGS. 25A-25C, conductive connectors 310 may be formed on the interconnect substrate 302, in accordance with some embodiments. The conductive connectors 310 may be similar to the conductive connectors 212 described previously for FIG. 18, in some cases. The conductive connectors 310 may be electrically connected to conductive routing within the interconnect substrate 302, and may be electrically connected to the photonic structure 200.

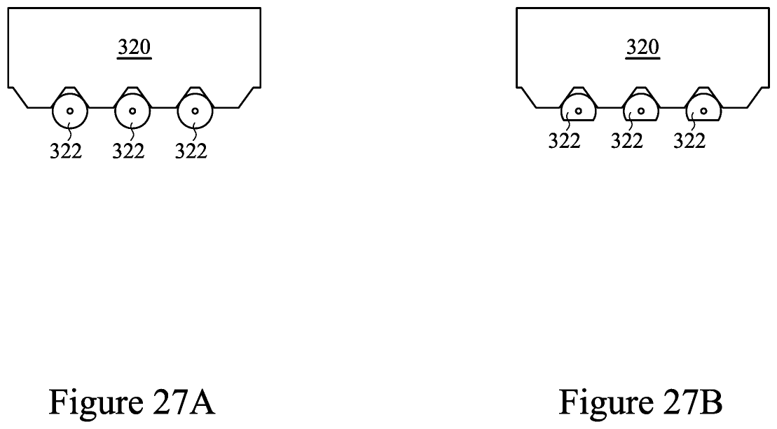

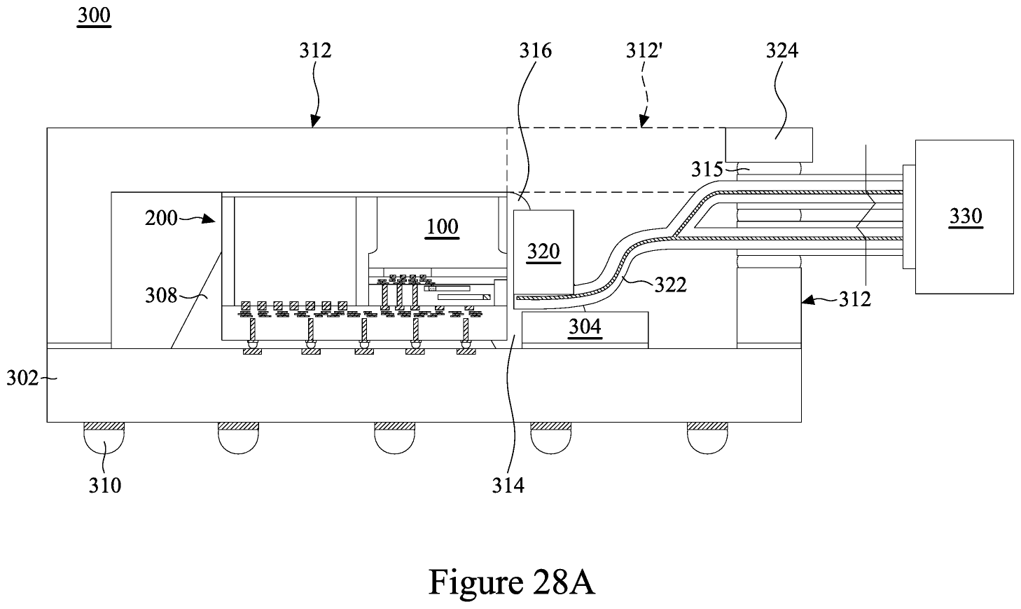

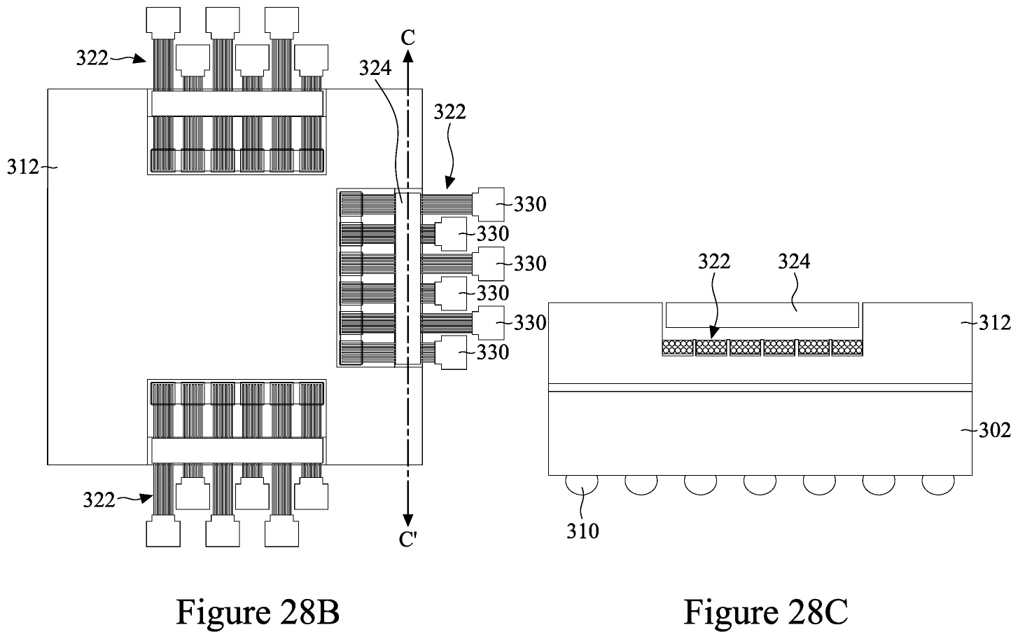

In FIGS. 26A, 26B, and 26C, one or more optical fibers 322 are attached to the lid 312 and are optically coupled to the photonic structure 200 to form a photonic system 300, in accordance with some embodiments. FIG. 26B illustrates a plan view, similar to FIG. 25B. FIG. 26A illustrates a cross-sectional view along the cross-section A-A′ shown in FIG. 25B, which may be similar to the cross-sectional view of FIG. 25A. FIG. 26C illustrates a cross-sectional view along the cross-section C-C′ shown in FIG. 26B. The optical fibers 322 may be individual optical fibers 322 or may be packaged in a fiber array or similar configuration. In some embodiments one or more optical fibers 322 may be secured near the photonic structure 200 by a fiber array unit 320 (described in greater detail in FIGS. 27A-27B). In some embodiments, each optical fiber 322 is optically coupled to a corresponding edge coupler 107 within the photonic structure 200 such that optical signals and/or optical power may be transmitted between the photonic structure 200 and the optical fiber 322. In some cases, the end of an optical fiber 322 that is opposite the photonic system 300 may be coupled to an optical interconnect such as a ferrule 330 (e.g., an MT ferrule or the like). Other optical interconnects are possible. In some embodiments, the optical fibers 322 may be secured to the lid 312 using a glue 315, which may be an adhesive, an optical glue, or the like. A lid cover 324 may be present over the opening 312′ to cover and protect the optical fibers 322, described in greater detail below for FIGS. 28A-28C.

The fiber array unit 320 holds optical fibers 322, and may be formed of one or more materials such as metal, ceramic, silicon (e.g., bulk silicon), a material such as those described for the lid 312 or the fiber support 304, or another material. The fiber array unit 320 may be placed on the fiber support 304, and in this manner the fiber support 304 can facilitate the vertical alignment of an optical fiber 322 with its corresponding edge coupler 107. In this manner, the fiber array unit 320 may be considered an “optical fiber holder” or the like. As shown in FIGS. 26B and 26C, multiple fiber array units 320 may be placed on the same fiber support 304, in some embodiments. In some embodiments, an optical glue 314 may be deposited between the photonic structure 200 and the optical fiber(s) 322. For example, the optical glue 314 may fill or partially fill the recess 134B. The optical glue 314 may secure the optical fiber 322 and/or the fiber array unit 320, and may also facilitate optical coupling between an edge coupler 107 and its corresponding optical fiber 322. In some embodiments, the optical glue 314 may extend on the fiber support 304, and may extend between the fiber support 304 and the optical fiber 322. In some embodiments, the optical glue 314 may extend on surfaces of the fiber array unit 320. In some embodiments, the optical glue 314 may be deposited after the optical fiber 322 has been aligned with an edge coupler 107 and/or placed on the fiber support 304.

In some embodiments, an optional protection material 316 may be deposited between the photonic structure 200 and the fiber array unit 320. The protection material 316 may be similar to the other protection materials described previously, or may be a different material. For example, the protection material 316 may be a glue, an epoxy, or the like. In some cases, the protection material 316 may cover portions of the optical glue 314. The protection material 316 may extend on sidewalls of the photonic structure 200 and/or on surfaces of the fiber array unit 320. In other embodiments, the protection material 316 is not present.

FIGS. 27A and 27B illustrate cross-sectional views of fiber array units 320 holding optical fibers 322, in accordance with some embodiments. As shown in FIGS. 27A-27B, a fiber array unit 320 may have multiple grooves (e.g., recesses), with an optical fiber 322 held within each groove. The fiber array units 320 shown in FIGS. 27A-27B are examples, and a fiber array unit 320 may have a different number of grooves (and corresponding held optical fibers 322) than shown, or may have a different shape or different dimensions than shown. In some embodiments, the fiber array unit 320 is oriented within a photonic system 300 such that the optical fibers 322 are at the bottom of the fiber array unit 320 (e.g., on the side of the fiber array unit 320 that faces the interconnect substrate 302). In some cases, the orientation of the fiber array unit 320 may be considered “upside-down.” By attaching the fiber array unit 320 with the optical fibers 322 at the bottom, the optical fibers 322 may be positioned closer to the interconnect substrate 302. This allows the edge couplers 107 of the photonic structure 200 to be formed closer to the bottom of the photonic structure 200. In this manner, the overall height of the photonic structure 200 and/or the photonic system 300 may be reduced.

In some embodiments, a polishing process may be performed to remove bottom portions of the optical fibers 322, as shown in FIG. 27B. The polishing process may comprise a CMP process, a grinding process, or another suitable polishing process. In some embodiments, after performing the polishing process, bottom surfaces of the optical fibers 322 of a fiber array unit 320 are substantially flat and coplanar. In this manner, polishing the optical fibers 322 may reduce the overall height of the optical fibers 322 and the fiber array unit 320. This also allows the optical fibers 322 to be located closer to the interconnect substrate 302. In some embodiments, the optical fibers 322 may be separated from a top surface of the interconnect substrate 302 by a vertical distance in the range of about 25 μm to about 70 μm, though other distances are possible. In this manner, polishing the optical fibers 322 can allow for improved flexibility of device design and improved flexibility of optical fiber alignment, and can reduce the overall height of the photonic structure 200 and/or the photonic system 300.

In FIGS. 28A, 28B, and 28C, an optional lid cover 324 is placed in the opening 312′, in accordance with some embodiments. FIG. 28B illustrates a plan view, similar to FIG. 26B. FIG. 28A illustrates a cross-sectional view along the cross-section A-A′ shown in FIG. 25B, which may be similar to the cross-sectional view of FIG. 26A. FIG. 26C illustrates a cross-sectional view along the cross-section C-C′ shown in FIG. 26B. In embodiments in which multiple openings 312′ are formed, multiple lid covers 324 may be placed, as shown in FIG. 28B. The lid cover 324 may be a material similar to the lid 312, the fiber support 304, the fiber array unit 320, or another material. In some embodiments, the lid cover 324 is attached using the glue 315 or a similar material. In some embodiments, top surfaces of the lid 312 and the lid cover 324 are approximately level. In other embodiments, a top surface of the lid 312 may be higher or lower than a top surface of the lid 312. The lid cover 324 may have a thickness less than, greater than, or about the same as that of the lid 312.

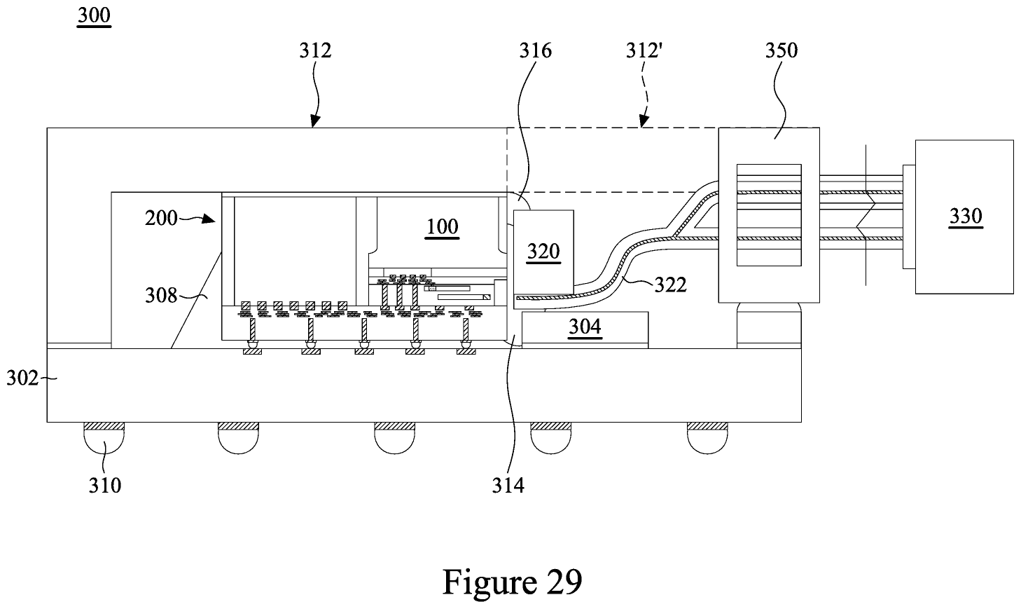

In other embodiments, the optical fibers 322 may be part of a fiber bundle or other suitable arrangement of optical fibers. As an example, FIG. 29 illustrates a photonic system 300 that is similar to the photonic system 300 of FIG. 28A, except that the optical fibers 322 are part of a fiber bundle 350. Similar to the photonic system 300 of FIG. 28A, the optical fibers 322 are supported by an optional fiber support 304 and are optically coupled to edge couplers 107 of a photonic structure 200. The fiber bundle 350 may be attached to the lid 312 or to the interconnect substrate 302 using a suitable adhesive, glue, epoxy, or the like. In some embodiments, a lid cover 324 is not present when a fiber bundle 350 is used.

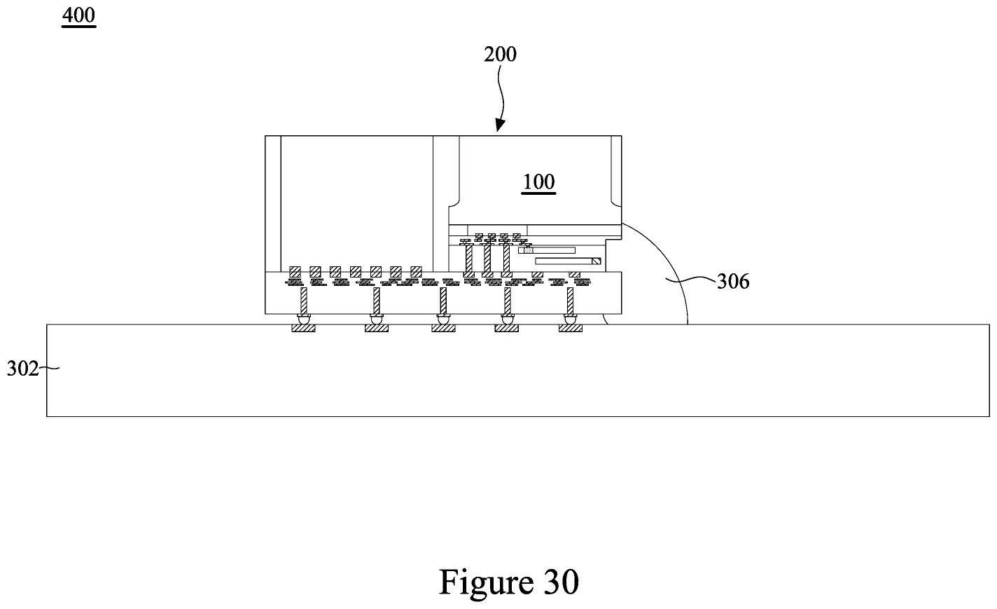

In other embodiments, a fiber support 304 may not be present. FIGS. 30 through 33 illustrate intermediate steps in the formation of a photonic system 400, in accordance with some embodiments. The photonic system 400 is similar to the photonic system 300 of FIG. 28A, except that a fiber support 304 is not used. Many of the steps, components, or materials of the photonic system 400 are similar to those described previously for the photonic system 300, and, as such, some similar details are not repeated below.

FIG. 30 illustrates a structure similar to that shown in FIG. 22 in which a photonic structure 200 is attached to an interconnect substrate 302. A protective material 306 is deposited on one or more sidewalls of the photonic structure 200. However, because a fiber support 304 is not used, the protective material 306 may extend from the sidewall(s) of the photonic structure 200 to the top surface of the interconnect substrate 302. The protective material 306 may fill or partially fill the recess 134B, similar to the step described for FIG. 22.

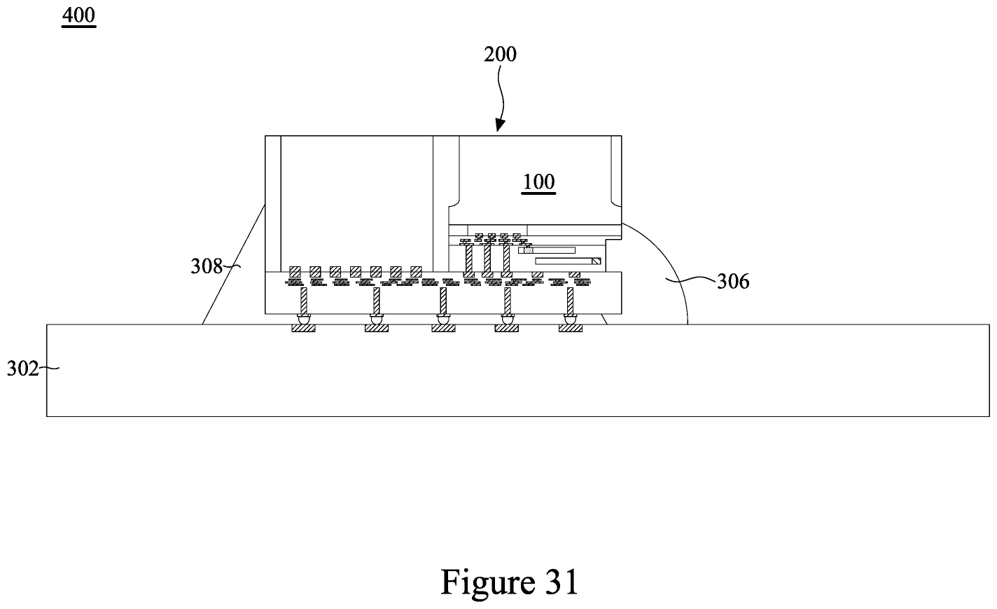

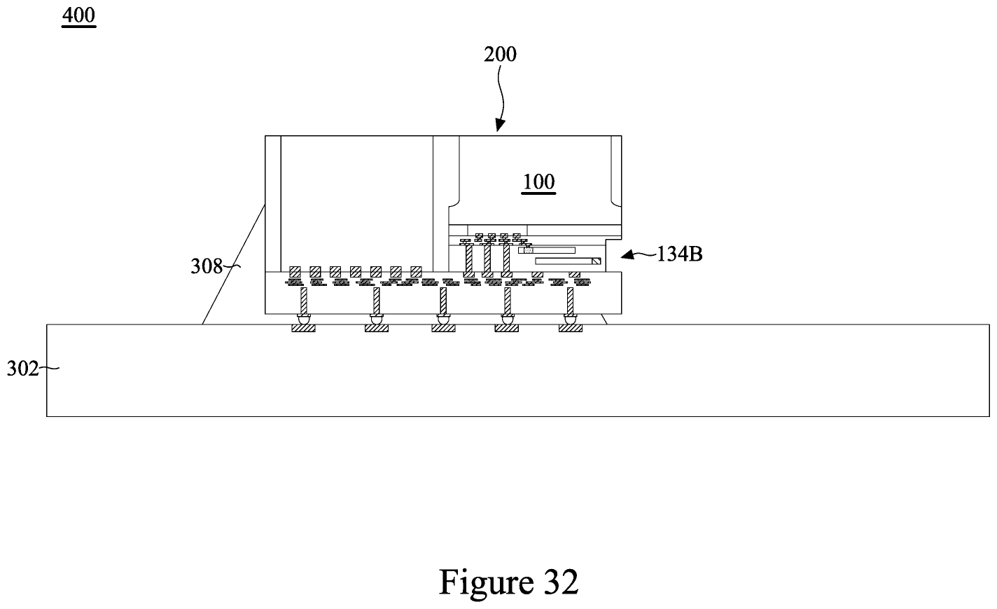

In FIG. 31, an underfill 308 is deposited between the photonic structure 200 and the interconnect substrate 302, similar to the step described for FIG. 23. For example, the protective material 306 blocks the underfill 308 from covering sidewalls that are adjacent edge couplers 107. In FIG. 32, the protection material 306 is removed using a suitable technique, similar to the step described for FIG. 24. For example, the protection material 306 may be removed using a flux cleaning process, using a solution of surfactants in water, or using another process.

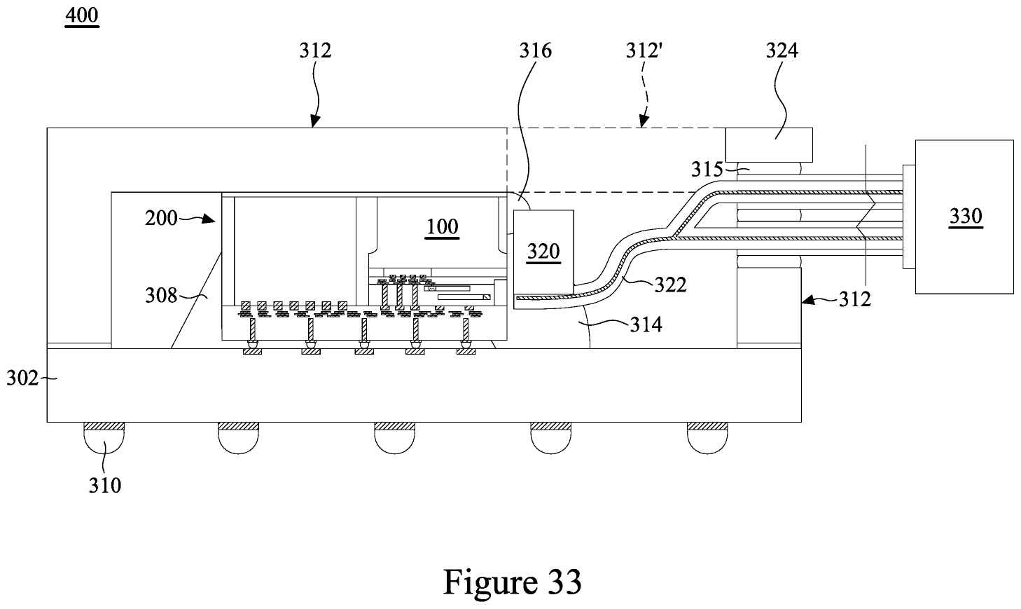

In FIG. 33, optical fibers 322 and a lid 312 are attached to form the photonic system 400, in accordance with some embodiments. As shown in FIG. 33, the fiber array unit 320 does not rest on a fiber support 304. However, an optical glue 314 may extend between the optical fibers 322 and the interconnect substrate 302, in some embodiments. The optical glue 314 may also extend from sidewalls adjacent the edge couplers 107 to the optical fibers 322, similar to the photonic system 300. An optical protective material 316 may be deposited over the optical glue 314 and/or the fiber array unit 320. A lid cover 324 may be attached, in some embodiments.

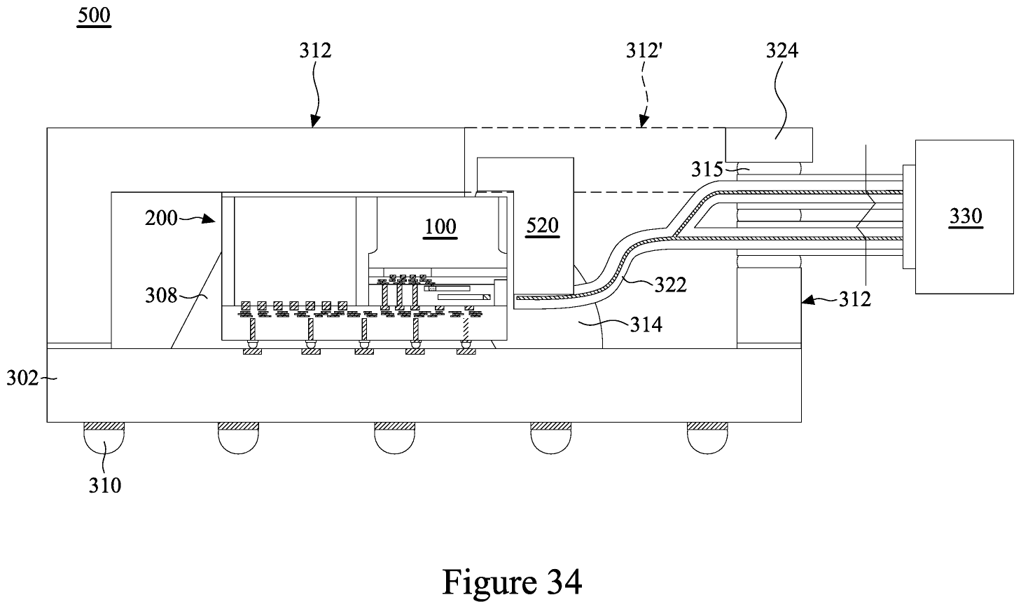

FIG. 34 shows a photonic system 500 that is similar to the photonic system 400 of FIG. 33, except that the fiber array unit 520 has an “L-shape,” in accordance with some embodiments. Also similar to FIG. 33, the fiber support 304 is not present, though a fiber support 304 may be present in other embodiments. In some embodiments, the opening 312′ extends over the photonic structure 200 such that a top surface region of the photonic structure 200 is not covered by the lid 312. The fiber array unit 520 is similar to the fiber array unit 320 described previously, except that the fiber array unit 520 includes a laterally protruding portion. As shown in FIG. 34, the laterally protruding portion of the fiber array unit 520 may extend over (e.g., overhang) the photonic structure 200. In some embodiments, the laterally protruding portion of the fiber array unit 520 may rest on the photonic structure 200. In other words, the photonic structure 200 may support the laterally protruding portion of the fiber array unit 520. In some embodiments, the shape of the fiber array unit 520 may be formed such that resting the laterally protruding portion on the photonic structure 200 also vertically aligns the optical fibers 322 with their corresponding edge couplers 107. In this manner, alignment of the optical fibers 322 to the edge couplers 107 may be facilitated. In some embodiments, an optical glue 314 may extend between the fiber array unit 520 and the photonic structure 200. In some embodiments, the optical glue 314 extends on a top surface of the photonic structure 200.

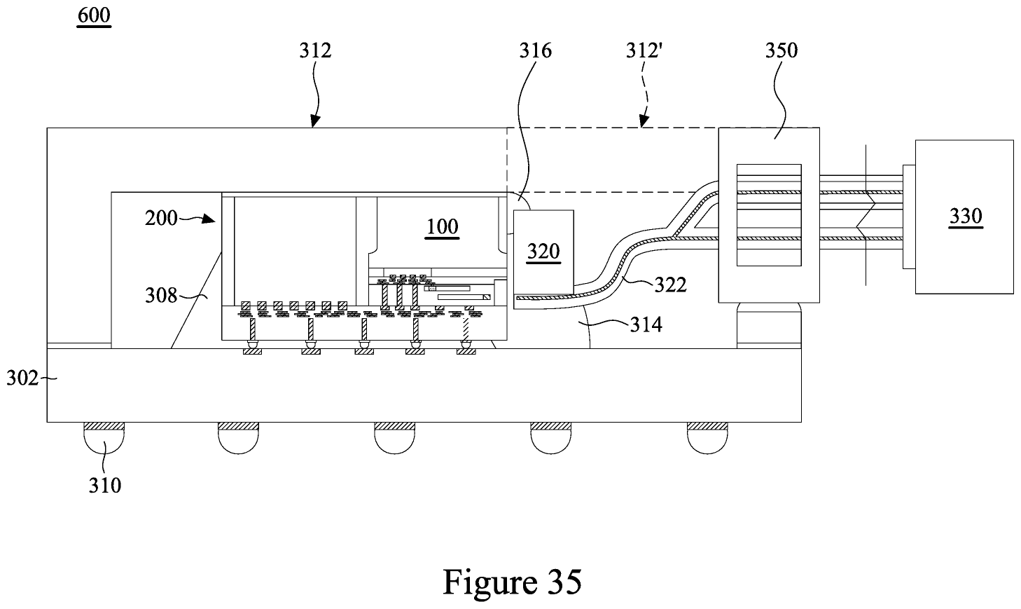

FIG. 35 shows a photonic system 600 that is similar to the photonic system 300 of FIG. 29, except that a fiber support 304 is not used. For example, the photonic system 600 includes a fiber bundle 350 with a fiber array unit 320 that is not supported by a fiber support 304. Similar to the photonic system 300, an optical glue 314 may extend between the fiber array unit 320 and the interconnect substrate 302. An optional protection material 316 may be formed between the fiber array unit 320 and the photonic structure 200, in some embodiments.

Embodiments may achieve advantages. The embodiments described herein allow for a photonic system to be formed with smaller size and improved operation. By utilizing both a plasma dicing process and a mechanical sawing process for singulation, sidewalls adjacent to edge couplers may have a smoother surface, which can improve optical coupling to the edge couplers and improve device speed and efficiency. Additionally, embodiments described herein utilize the application of multiple protective layers during processing that protect these sidewalls from damage, which can maintain the smooth quality of the sidewalls throughout manufacturing. In some embodiments, a recess may be formed in the sidewalls adjacent the edge couplers, which can further protect the smooth quality of the sidewalls from damage or debris. Additionally, by holding optical fibers along the bottom of a fiber array unit, the overall height of the photonic system may be reduced, while allowing for improved alignment flexibility. Using photonic packages and optical communication in this manner can provide reduced optical loss, higher bandwidth, improved efficiency, and improved high-speed communication of a photonic system or quantum computing system.

In accordance with an embodiment, a method includes connecting a photonic package to a substrate, wherein the photonic package includes a waveguide and an edge coupler that is optically coupled to the waveguide; connecting a semiconductor device to the substrate adjacent the photonic package; depositing a first protection material on a first sidewall of the photonic package that is adjacent the edge coupler; encapsulating the photonic package and the semiconductor device with an encapsulant; performing a first sawing process through the encapsulant and the substrate, wherein the first sawing process exposes the first protection material; and removing the first protection material to expose the first sidewall of the photonic package. In an embodiment, the method includes performing a plasma etching process on the photonic package to form a lateral recess, wherein the first sidewall is within the lateral recess. In an embodiment, the lateral recess has a lateral depth between 0 μm and 10 μm. In an embodiment, the photonic package includes a support, and wherein the first sawing process exposes a second sidewall of the support. In an embodiment, removing the first protection material includes performing a flux cleaning process. In an embodiment, the method includes attaching an optical fiber to the photonic package, wherein the optical fiber is optically coupled to the edge coupler. In an embodiment, the method includes, before connecting the photonic package to the substrate, performing a singulation process on the photonic package, wherein the singulation process includes performing a plasma etching process to form a first recess in a bottom side of the photonic package and performing a second sawing process to form a second recess in a top side of the photonic package, wherein the second recess extends into the first recess. In an embodiment, forming the first recess exposes the first sidewall of the photonic package.

In accordance with an embodiment, a method includes attaching a photonic structure to a substrate, wherein the photonic structure includes a waveguide near a first sidewall of the photonic structure; attaching a fiber support structure to the substrate adjacent the first sidewall of the photonic structure; depositing a sacrificial material on the first sidewall; depositing an underfill between the photonic structure and the substrate; removing the sacrificial material to expose the first sidewall; attaching an optical fiber to the fiber support structure, wherein the optical fiber is optically coupled to the waveguide; and depositing an optical glue that extends from the first sidewall to the optical fiber. In an embodiment, the underfill is deposited on the substrate adjacent a second sidewall of the photonic structure that is opposite the first sidewall. In an embodiment, the method includes attaching a lid to the substrate, wherein the optical fiber extends through an opening in the lid. In an embodiment, the method includes attaching a lid cover to the optical fiber within the opening of the lid. In an embodiment, the optical fiber is held by a groove in a fiber array unit, wherein the groove faces the substrate. In an embodiment, the method includes depositing a protection material over the optical glue. In an embodiment, the optical glue extends between the optical fiber and the fiber support structure.

In accordance with an embodiment, a device includes a photonic package bonded to a first interconnect substrate, wherein the photonic package includes edge couplers; a second interconnect substrate, wherein the first interconnect substrate is bonded to the second interconnect substrate; an optical fiber holder with multiple grooves on a bottom side of the optical fiber holder; optical fibers, wherein each optical fiber is held by a respective groove and is optically coupled to a respective edge coupler; and an optical adhesive between the photonic package and the optical fibers. In an embodiment, the edge couplers are adjacent a first sidewall surface of the photonic package, wherein the first sidewall surface is recessed from a second sidewall surface of the photonic package. In an embodiment, the optical fibers are a fiber bundle. In an embodiment, the device includes a fiber support structure attached to the second interconnect substrate, wherein the fiber support structure is between the optical fiber holder and the second interconnect substrate. In an embodiment, portions of the optical fibers that are within the grooves have flat bottom surfaces.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
connecting a photonic package to a substrate, wherein the photonic package comprises a waveguide and an edge coupler that is optically coupled to the waveguide;
connecting a semiconductor device to the substrate adjacent the photonic package;
depositing a first protection material on a first sidewall of the photonic package that is adjacent the edge coupler;
encapsulating the photonic package and the semiconductor device with an encapsulant;
performing a first sawing process through the encapsulant and the substrate, wherein the first sawing process exposes the first protection material; and
removing the first protection material to expose the first sidewall of the photonic package.

2. The method of claim 1 further comprising performing a plasma etching process on the photonic package to form a lateral recess, wherein the first sidewall is within the lateral recess.

3. The method of claim 2, wherein the lateral recess has a lateral depth between 0 μm and 10 μm.

4. The method of claim 1, wherein the photonic package comprises a support, and wherein the first sawing process exposes a second sidewall of the support.

5. The method of claim 1, wherein removing the first protection material comprises performing a flux cleaning process.

6. The method of claim 1 further comprising attaching an optical fiber to the photonic package, wherein the optical fiber is optically coupled to the edge coupler.

7. The method of claim 1 further comprising, before connecting the photonic package to the substrate, performing a singulation process on the photonic package, wherein the singulation process comprises:
performing a plasma etching process to form a first recess in a bottom side of the photonic package; and
performing a second sawing process to form a second recess in a top side of the photonic package, wherein the second recess extends into the first recess.

8. The method of claim 7, wherein forming the first recess exposes the first sidewall of the photonic package.

9. A method, comprising:
attaching a photonic structure to a substrate, wherein the photonic structure comprises a waveguide near a first sidewall of the photonic structure;
attaching a fiber support structure to the substrate adjacent the first sidewall of the photonic structure;
depositing a sacrificial material on the first sidewall;
depositing an underfill between the photonic structure and the substrate;
removing the sacrificial material to expose the first sidewall;
attaching an optical fiber to the fiber support structure, wherein the optical fiber is optically coupled to the waveguide; and
depositing an optical glue that extends from the first sidewall to the optical fiber.

10. The method of claim 9, wherein the underfill is deposited on the substrate adjacent a second sidewall of the photonic structure that is opposite the first sidewall.

11. The method of claim 9 further comprising attaching a lid to the substrate, wherein the optical fiber extends through an opening in the lid.

12. The method of claim 11 further comprising attaching a lid cover to the optical fiber within the opening of the lid.

13. The method of claim 9, wherein the optical fiber is held by a groove in a fiber array unit, wherein the groove faces the substrate.

14. The method of claim 9 further comprising depositing a protection material over the optical glue.

15. The method of claim 9, wherein the optical glue extends between the optical fiber and the fiber support structure.

16. A device, comprising:
a photonic package bonded to a first interconnect substrate, wherein the photonic package comprises a plurality of edge couplers;
a second interconnect substrate, wherein the first interconnect substrate is bonded to the second interconnect substrate;
an optical fiber holder comprising a plurality of grooves on a bottom side of the optical fiber holder;
a plurality of optical fibers, wherein each optical fiber is held by a respective groove and is optically coupled to a respective edge coupler; and
an optical adhesive between the photonic package and the plurality of optical fibers.

17. The device of claim 16, wherein the plurality of edge couplers are adjacent a first sidewall surface of the photonic package, wherein the first sidewall surface is recessed from a second sidewall surface of the photonic package.

18. The device of claim 16, wherein the plurality of optical fibers comprises a fiber bundle.

19. The device of claim 16 further comprising a fiber support structure attached to the second interconnect substrate, wherein the fiber support structure is between the optical fiber holder and the second interconnect substrate.

20. The device of claim 16, wherein portions of the plurality of optical fibers that are within the plurality of grooves have flat bottom surfaces.
